(19) United States
(12) Patent Application Publication
(10) Pub. No.: US 2026/0347995 A1
(43) Pub. Date: Nov. 5, 2026

(54) DEPOSITION MASK, METHOD OF MANUFACTURING THE SAME, AND ELECTRONIC DEVICE MANUFACTURED BY USING THE SAME

(71) Applicant: Samsung Display Co., Ltd., Yongin-si (KR)

(72) Inventor: Duck Jung LEE, Yongin-si (KR)

(21) Appl. No.: 19/427,416

(22) Filed: Dec. 19, 2025

(30) Foreign Application Priority Data
Apr. 30, 2025 (KR) 10-2025-0057098

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes a mask substrate defining a cell opening, a buffer inorganic film on the mask substrate and including an eaves region exposed by the cell opening, and a membrane on the eaves region and defining a plurality of pixel openings connected to the cell opening.

### CROSS-REFERENCE TO RELATED APPLICATION

The present application claims priority to and the benefit of Korean Patent Application No. 10-2025-0057098, filed on Apr. 30, 2025, in the Korean Intellectual Property Office, the entire content of which is incorporated herein by reference.

### BACKGROUND

### 1. Field

Embodiments of the present disclosure relate to a deposition mask, a method of manufacturing the same, and an electronic device manufactured by using the same.

### 2. Description of the Related Art

Wearable devices capable of forming focuses at a distance close to their user’s eyes have been developed in the form of glasses or helmets. Such a wearable device may provide an augmented reality (AR) screen or a virtual reality (VR) screen to a user. For example, the wearable device may be a head mounted display (HMD) device or AR glasses.

Such HMD devices or AR glasses may include a display specification of approximately 3000 PPI (pixels per inch) or higher to allow users to use them for a long time without adverse symptoms, such as dizziness. To this end, organic light-emitting diodes on silicon (OLEDoS) technology have been emerging for use in high-resolution small organic light-emitting display devices. The OLEDoS is a technology in which organic light-emitting diodes (OLED) are arranged on a semiconductor substrate on which complementary metal oxide semiconductor (CMOS) elements may be arranged.

In order to manufacture a display panel with a high resolution of about 3000 PPI or higher, a high-resolution deposition mask may be used. For example, a deposition mask may be used as a shadow mask in a deposition process for forming light-emitting layers on a backplane substrate. In the deposition process, the backplane substrate may be arranged on the deposition mask, and a deposition source for providing a vapor deposition material may be arranged under the deposition mask.

For example, the deposition mask may be manufactured by forming a membrane having a plurality of pixel openings on a mask substrate, and partially removing the mask substrate to form cell openings that expose the pixel openings. However, deformation of the deposition mask may occur due to residual stress in the membrane. For example, global warpage, in which the deposition mask is deformed as a whole, and cell warpage, in which mask cell regions of the membrane are deformed, may occur, and thus, the pixel position accuracy (PPA), size uniformity, and/or the like, of the light-emitting layers may be degraded.

The above information disclosed in this Background section is intended to enhance understanding of the background of the disclosure and may contain information that does not constitute prior art.

### SUMMARY

Aspects of one or more embodiments of the present disclosure are directed to a deposition mask having an improved structure capable of reducing deformation, a method of manufacturing the same, and an electronic device manufactured by using the same.

However, embodiments of the present disclosure are not limited to those set forth herein. Additional aspects will be set forth in part in the description which follows and, in part, will be apparent from the description, or may be learned by practice of the presented embodiments of the disclosure.

In one or more embodiments of the present disclosure, a deposition mask includes a mask substrate defining a cell opening, a buffer inorganic film located on the mask substrate and including an eaves region exposed by the cell opening, and a membrane located on the eaves region and defining a plurality of pixel openings connected to the cell opening.

In one or more embodiments of the present disclosure, the buffer inorganic film may have residual compressive stress, and the membrane may have residual tensile stress.

In one or more embodiments of the present disclosure, a width of the eaves region may be in a range of about 1 μm to about 100 μm.

In one or more embodiments of the present disclosure, an edge region of the membrane may be located on the eaves region, and a width of a region where the edge region of the membrane and the eaves region overlap each other may be in a range of about 0.5 μm to about 50 μm.

In one or more embodiments of the present disclosure, the mask substrate may include a rib region defining the cell opening, the buffer inorganic film may include a grid region located on the rib region, and the eaves region may extend from the grid region and may be positioned higher than the grid region.

In one or more embodiments of the present disclosure, the deposition mask may further include a spacer pattern located on the grid region.

In one or more embodiments of the present disclosure, the spacer pattern may include a first spacer pattern located on the grid region, and a second spacer pattern located on the first spacer pattern. The second spacer pattern may include the same material as the membrane.

In one or more embodiments of the present disclosure, the deposition mask may further include a mask alignment key located on an edge region of the buffer inorganic film. The first spacer pattern may include the same material as the mask alignment key.

In one or more embodiments of the present disclosure, the deposition mask may further include a protective film pattern located on the mask alignment key. The protective film pattern may include the same material as the membrane.

In one or more embodiments of the present disclosure, a method of manufacturing a deposition mask includes forming a buffer inorganic film on a mask substrate, forming a membrane having a plurality of pixel openings on the buffer inorganic film, forming a preliminary cell opening that partially exposes the buffer inorganic film by partially removing the mask substrate, forming a buffer opening that partially exposes the membrane by removing a portion of the buffer inorganic film exposed by the preliminary cell opening, and forming a cell opening that partially exposes the buffer inorganic film by expanding the preliminary cell opening. The membrane is located on an eaves region of the buffer inorganic film exposed by the cell opening.

In one or more embodiments of the present disclosure, the forming of the membrane may include forming a front inorganic film on the buffer inorganic film, and partially removing the front inorganic film to form the plurality of pixel openings and the membrane. The buffer inorganic film may have residual compressive stress, and the front inorganic film may have residual tensile stress.

In one or more embodiments of the present disclosure, the method may further include forming a mask alignment key on an edge region of the buffer inorganic film, and forming a protective film pattern on the mask alignment key. The protective film pattern may be formed concurrently (e.g., simultaneously) with the plurality of pixel openings and the membrane by partially removing the front inorganic film.

In one or more embodiments of the present disclosure, the method may further include forming a first spacer pattern on the buffer inorganic film, and forming a second spacer pattern on the first spacer pattern. The first spacer pattern may be formed concurrently (e.g., simultaneously) with the mask alignment key, and the second spacer pattern may be formed concurrently (e.g., simultaneously) with the protective film pattern.

In one or more embodiments of the present disclosure, the buffer inorganic film may be formed on a front surface of the mask substrate, and the forming of the preliminary cell opening may include forming an intermediate inorganic film on a rear surface of the mask substrate, forming a rear inorganic film on the intermediate inorganic film, forming a rear opening that partially exposes the intermediate inorganic film through the rear inorganic film, forming a preliminary intermediate opening that partially exposes the rear surface of the mask substrate through a portion of the intermediate inorganic film exposed by the rear opening, and forming the preliminary cell opening by performing an etching process using (e.g., utilizing) the rear inorganic film and the intermediate inorganic film as etching masks.

In one or more embodiments of the present disclosure, the preliminary intermediate opening may have a width smaller than that of the rear opening, and the forming of the cell opening may include forming an intermediate opening by removing a remaining portion of the portion of the intermediate inorganic film exposed by the rear opening, and expanding the preliminary cell opening by removing inner surface portions defining (of) the preliminary cell opening.

In one or more embodiments of the present disclosure, the forming of the intermediate opening is performed concurrently (e.g., simultaneously) with the forming of the buffer opening.

In one or more embodiments of the present disclosure, the method may further include forming an etch stop film on the buffer inorganic film and the membrane, and removing the etch stop film after forming the buffer opening.

In one or more embodiments of the present disclosure, an edge region of the membrane may be located on the eaves region, and a region where the edge region of the membrane and the eaves region overlap each other may have a width smaller than that of the eaves region.

In one or more embodiments of the present disclosure, an electronic device includes a display panel. The display panel includes a backplane substrate and a plurality of light-emitting layers formed on the backplane substrate by using (e.g., utilizing) a deposition mask. The deposition mask includes a mask substrate having (e.g., defining) a cell opening, a buffer inorganic film located on the mask substrate and including an eaves region exposed by the cell opening, and a membrane located on the eaves region and having (e.g., defining) a plurality of pixel openings connected to the cell opening. The plurality of light-emitting layers are formed by a deposition process that provides a vapor light-emitting material onto the backplane substrate through the cell opening and the pixel openings.

In one or more embodiments of the present disclosure, the electronic device may further include at least one of a processor, a memory, or a power module.

In one or more embodiments of the present disclosure, a membrane may be located on an eaves region of a buffer inorganic film exposed by a cell opening. The buffer inorganic film may have residual compressive stress, and the membrane may have residual tensile stress. Therefore, deformation of the membrane may be reduced by the residual compressive stress of the buffer inorganic film and the residual tensile stress of the membrane.

For example, one or more embodiments provide a deposition mask and related manufacturing method that improves pixel position accuracy and reduces global and cell warpage by controlling residual stresses in multiple layers. The deposition mask may include optional features such as spacer patterns, mask alignment keys, and protective film patterns to facilitate alignment and handling during deposition. The method may further include sequential or concurrent formation of buffer openings, intermediate openings, and cell openings to expose membranes having pixel openings, thereby enabling precise deposition of light-emitting materials through the mask onto a backplane substrate. These structural and process features collectively support high-resolution display panels and electronic devices incorporating such panels, as described herein.

Other features and embodiments may be apparent from the following detailed description and the drawings.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a block diagram of an electronic device according to one or more embodiments of the present disclosure;

FIG. 2 shows schematic diagrams of electronic devices according to embodiments of the present disclosure;

FIG. 3 is an exploded perspective view of a display device according to one or more embodiments of the present disclosure;

FIG. 4 is a block diagram of the display device of FIG. 3, according to one or more embodiments of the present disclosure;

FIG. 5 is an equivalent circuit diagram of a first sub-pixel of FIG. 4, according to one or more embodiments of the present disclosure;

FIG. 6 is a schematic plan view of a display panel of FIG. 3, according to one or more embodiments of the present disclosure;

FIG. 7 is a schematic enlarged plan view of a portion of a display area of FIG. 6, according to one or more embodiments of the present disclosure;

FIG. 8 is a schematic enlarged plan view of a portion of a display area of FIG. 6, according to one or more embodiments of the present disclosure;

FIG. 9 is a schematic cross-sectional view of the display panel taken along the line I1-I1' of FIG. 7, according to one or more embodiments of the present disclosure;

FIG. 10 is a schematic cross-sectional view of the display panel taken along the line I1-I1' of FIG. 7, according to one or more embodiments of the present disclosure;

FIG. 11 is a schematic cross-sectional view of the display panel taken along the line I1-I1' of FIG. 7, according to one or more embodiments of the present disclosure;

FIG. 12 is a schematic perspective view of a head mounted display, according to one or more embodiments of the present disclosure;

FIG. 13 is a schematic exploded perspective view of the head mounted display of FIG. 12, according to one or more embodiments of the present disclosure;

FIG. 14 is a schematic perspective view of a head mounted display, according to one or more embodiments of the present disclosure;

FIG. 15 is a schematic diagram illustrating a deposition mask and a deposition apparatus according to one or more embodiments of the present disclosure;

FIG. 16 is a schematic bottom view of a backplane substrate shown in FIG. 15, according to one or more embodiments of the present disclosure;

FIG. 17 is a schematic plan view of a deposition mask shown in FIG. 15, according to one or more embodiments of the present disclosure;

FIG. 18 is a schematic plan view illustrating membranes of FIG. 17, according to one or more embodiments of the present disclosure;

FIG. 19 is a schematic cross-sectional view taken along the line I2-I2' of FIG. 18, according to one or more embodiments of the present disclosure;

FIG. 20 is a schematic cross-sectional view of mask alignment keys shown in FIG. 17, according to one or more embodiments of the present disclosure;

FIG. 21 is a schematic cross-sectional view of spacer patterns of FIG. 17, according to one or more embodiments of the present disclosure; and

FIGS. 22 − 34 are schematic cross-sectional views illustrating a method of manufacturing a deposition mask according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The terminology used herein is for the purpose of describing particular embodiments only and is not intended to be limiting of the present disclosure. As used herein, “a”, “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” refers to “and/or.” As used herein, the term “and/or” includes any and all combinations of one or more of the associated listed items.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions "at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Further, the use of “may” when describing embodiments of the present disclosure refers to “one or more embodiments of the present disclosure.”

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Spatially relative terms, such as “on,” “below,” “bottom,” “lower,” “under,” “above,” “upper,” “top” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied. As used herein, the term “substantially,” “about,” “approximately,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ± 30 %, 20 %, 10 %, 5 % of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may have rough and/or nonlinear features. Moreover, sharp angles that are illustrated may be rounded. Thus, the regions illustrated in the drawings are schematic in nature and their shapes are not intended to illustrate the precise shape of a region and are not intended to limit the scope of the present claims. In addition, the relative sizes (e.g., including lengths, widths and thicknesses) of elements, layers, and regions may be exaggerated for clarity in the drawings.

Hereinafter, embodiments will be described in more detail with reference to the accompanying drawings.

The display device according to one or more embodiments of the present disclosure can be applied to one or more suitable electronic devices. The electronic device according to the one or more embodiments of the present disclosure includes the display device described above, and may further include modules or devices having additional functions in addition to the display device.

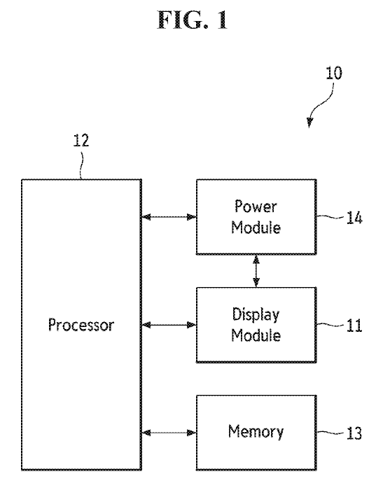

FIG. 1 is a block diagram of an electronic device according to one or more embodiments of the present disclosure.

Referring to FIG. 1, the electronic device 10 according to one or more embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and/or a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 10.

At least one of the components of the electronic device 10 according to the one or more embodiments of the present disclosure may be included in the display device 20 according to one or more embodiments of the present disclosure. In addition, some modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

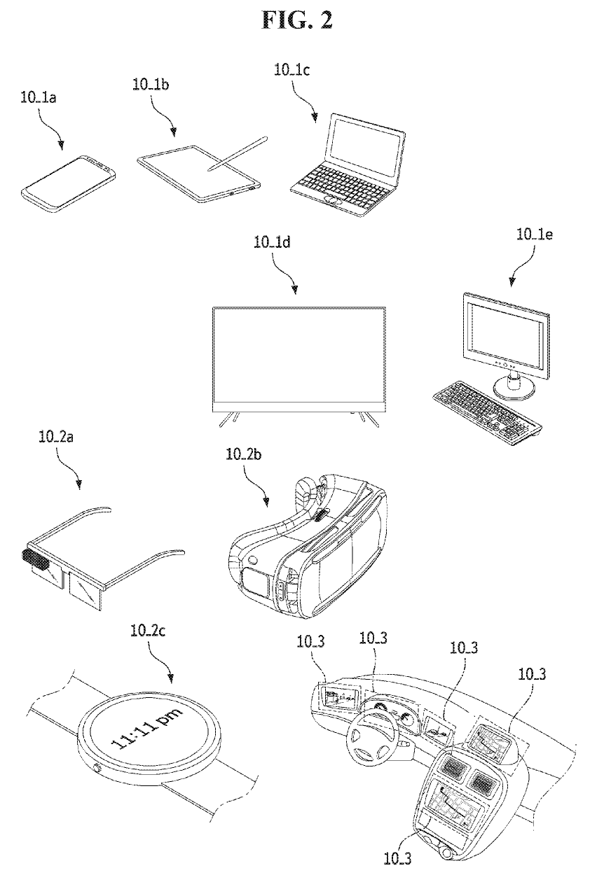

FIG. 2 shows schematic diagrams of electronic devices according to one or more suitable embodiments of the present disclosure.

Referring to FIG. 2, one or more suitable electronic devices to which display devices 20 according to one or more embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and/or dashboard of an automobile.

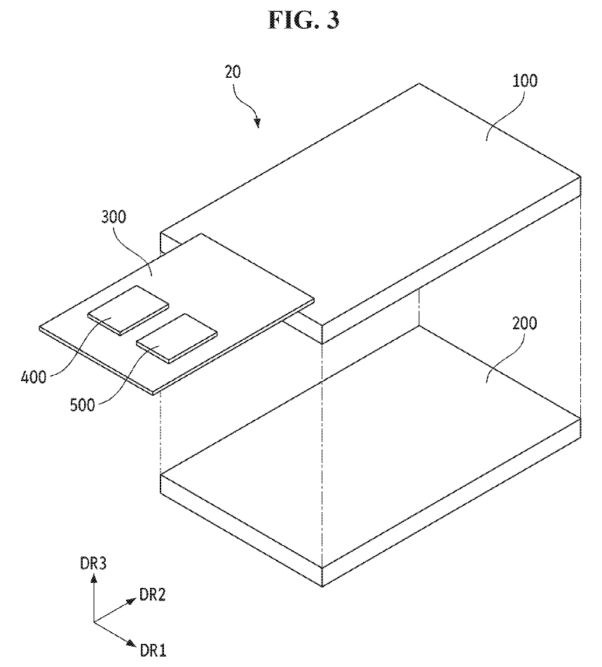

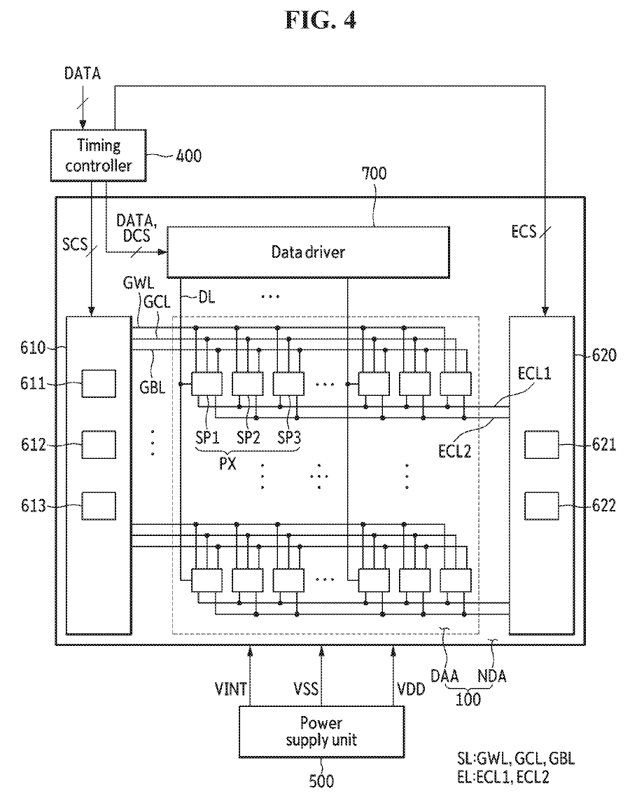

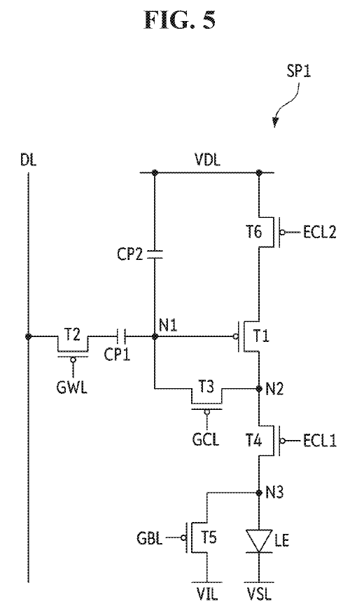

FIG. 3 is an exploded perspective view illustrating a display device according to one or more embodiments of the present disclosure. FIG. 4 is a block diagram illustrating the display device of FIG. 3 in a plan view, according to one or more embodiments of the present disclosure.

Referring to FIGS. 3 and 4, a display device 20 according to one or more embodiments may be a device displaying a moving image or a still image. A display device 20 according to one or more embodiments may be used as the electronic device 10 or the display module 11 of the electronic device 10. For example, the display device 20 according to one or more embodiments may be applied to portable electronic devices 10 such as a mobile phone, a smartphone, a tablet personal computer, a mobile communication terminal, an electronic organizer, an electronic book, a portable multimedia player (PMP), a navigation system, an ultra mobile PC (UMPC), and/or the like. The display device 20 according to one or more embodiments may be applied as a display module 11 of electronic devices 10 such as a television, a laptop, a monitor, a billboard, or an Internet-of-Things (IoT) terminal, and/or the like. The display device 20 according to one or more embodiments may be applied to electronic devices 10 such as a smart watch, a watch phone, a head mounted display (HMD) for implementing virtual reality and augmented reality, and/or the like.

The display device 20 according to one or more embodiments may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a set or predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the present disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 4.

The plurality of pixels PX may be arranged in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

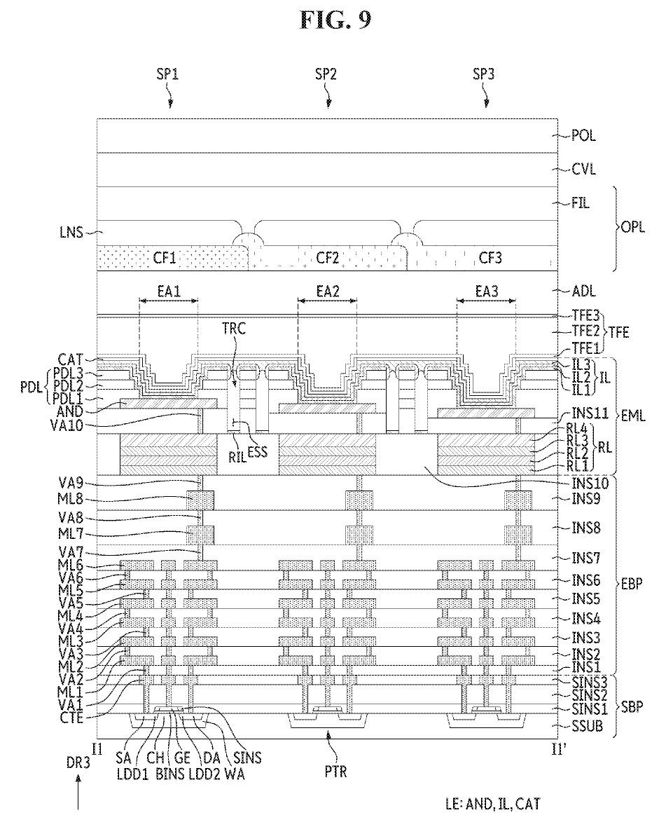

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and arranged on a semiconductor substrate SSUB (see, e.g., FIG. 9). For example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be arranged in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see, e.g., FIG. 9) through a semiconductor process. For example, the plurality of scan transistors and the plurality of light-emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see, e.g., FIG. 9) through a semiconductor process. For example, the plurality of data transistors may be formed of CMOS, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In such embodiments, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on one surface of the display panel 100, for example, on the rear surface thereof. The heat dissipation layer 200 serves to dissipate heat generated from the display panel 100. The heat dissipation layer 200 may include a material having high thermal conductivity, for example, graphite or a metal such as silver (Ag), copper (Cu), aluminum (Al), and/or the like.

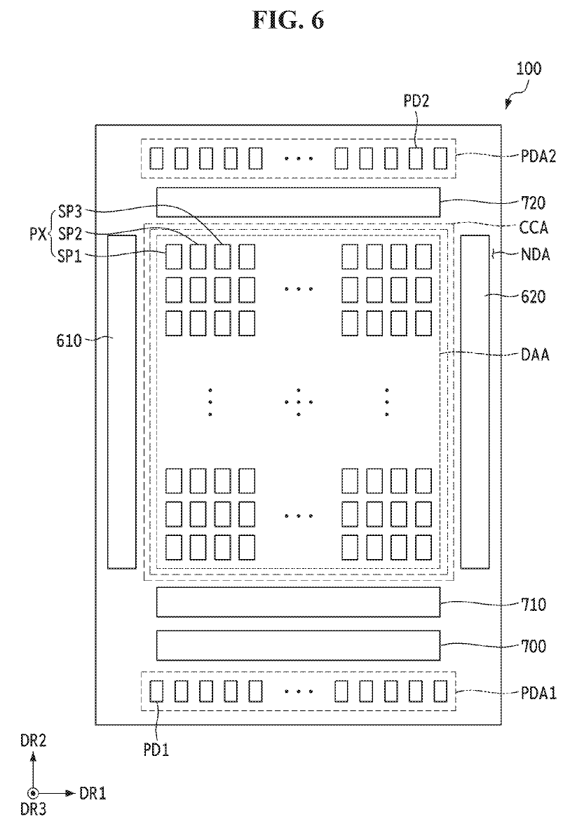

The circuit board 300 may be electrically connected to a plurality of first pads PD1 (see, e.g., FIG. 6) of a first pad portion PDA1 (see, e.g., FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In such embodiments, one end of the circuit board 300 may be arranged on the rear surface of the display panel 100 and/or the rear surface of the heat dissipation layer 200. The other end of the circuit board 300 may be connected to the plurality of first pads PD1 (see, e.g., FIG. 6) of the first pad portion PDA1 (see, e.g., FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described in more detail later in conjunction with FIG. 5.

Each of the timing control circuit 400 and the power supply circuit 500 may be formed as an integrated circuit (IC) and attached to one surface of the circuit board 300. In such embodiments, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the emission driver 620, and the data driver 700. In such embodiments, the timing control circuit 400 may include a plurality of timing transistors, and each power supply circuit 500 may include a plurality of power transistors. The plurality of timing transistors and the plurality of power transistors may be formed on the semiconductor substrate SSUB (see, e.g., FIG. 9) through a semiconductor process. For example, the plurality of timing transistors and the plurality of power transistors may be formed of CMOS, but the present disclosure is not limited thereto. Each of the timing control circuit 400 and the power supply circuit 500 may be arranged between the data driver 700 and the first pad portion PDA1 (see, e.g., FIG. 6).

FIG. 5 is an equivalent circuit diagram illustrating an example of a first sub-pixel shown in FIG. 4, according to one or more embodiments of the present disclosure.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer arranged between the first electrode and the second electrode, but the present disclosure is not limited thereto. For example, the light-emitting element LE may be an inorganic light-emitting element including a first electrode, a second electrode, and an inorganic semiconductor arranged between the first electrode and the second electrode, in which case the light-emitting element LE may be a micro light-emitting diode.

The first transistor T1 may be a driving transistor that controls a source-drain current (hereinafter referred to as "driving current") flowing between the source electrode and the drain electrode thereof according to a voltage applied to the gate electrode thereof.

A second transistor T2 may be arranged between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be arranged between the first node N1 and the second node N2. The third transistor T3 is turned on by the control scan signal of the control scan line GCL to connect the first node N1 to the second node N2. For this reason, if (e.g., when) the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE. A fifth transistor T5 may be arranged between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE.

The sixth transistor T6 may be arranged between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type (kind) MOSFET, but the present disclosure is not limited thereto. Each of the first to sixth transistors T1 to T6 may be an N-type (kind) MOSFET. In one or more embodiments, some of the first to sixth transistors T1 to T6 may be P-type (kind) MOSFETs, and each of the remaining transistors may be an N-type (kind) MOSFET.

Although it is illustrated in FIG. 5 that the first sub-pixel SP1 includes six transistors T1 to T6 and two capacitors CP1 and CP2, it should be noted that the equivalent circuit diagram of the first sub-pixel SP1 is not limited to that shown in FIG. 5. For example, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 may not be repeated in the present disclosure.

FIG. 6 is a schematic plan view illustrating an example of a display panel shown in FIG. 3, according to one or more embodiments of the present disclosure.

Referring to FIG. 6, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be arranged on the first side of the display area DAA, and the emission driver 620 may be arranged on the second side of the display area DAA. For example, the scan driver 610 may be arranged on one side of the display area DAA in the first direction DR1, and the emission driver 620 may be arranged on the other side of the display area DAA in the first direction DR1. However, the present disclosure is not limited thereto, and the scan driver 610 and the emission driver 620 may be arranged on both (e.g., either) the first side and/or the second side of the display area DAA.

The first pad portion PDA1 may include the plurality of first pads PD1 connected to pads or bumps of the circuit board 300 through a conductive adhesive member. The first pad portion PDA1 may be arranged on the third side of the display area DAA. For example, the first pad portion PDA1 may be arranged on one side of the display area DAA in the second direction DR2. The first pad portion PDA1 may be arranged outside the data driver 700 in the second direction DR2 relative to the location of the display area DAA.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be arranged on the fourth side of the display area DAA. For example, the second pad portion PDA2 may be arranged on the other side of the display area DAA in the second direction DR2 relative to the third side of the display area DAA. The second pad portion PDA2 may be arranged outside the second distribution circuit 720 in the second direction DR2 relative to the location of the display area DAA.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to P (P is a positive integer of 2 or more) data lines DL, and as a result, the number of the plurality of first pads PD1 may be reduced. In other words, each of the first pads PD1 may supply data voltages to multiple data lines DL, thus reducing the number of first pads PD1. The first distribution circuit 710 may be arranged on the third side of the display area DAA of the display panel 100. For example, the first distribution circuit 710 may be arranged on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be arranged on the fourth side of the display area DAA of the display panel 100. For example, the second distribution circuit 720 may be arranged on the other side of the display area DAA in the second direction DR2.

A cathode connection part CCA may be a region where a second electrode CAT (see, e.g., FIG. 9) of a display element layer EML (see, e.g., FIG. 9) is connected to the first driving voltage line VSL of the non-display area NDA. The cathode connection part CCA may be arranged outside at least one side of the display area DAA. For example, the cathode connection part CCA may be arranged outside at least on one side among the left side, the right side, the upper side, and the lower side of the display area DAA. In one or more embodiments, the cathode connection part CCA may be arranged to be around (e.g., surround) the display area DAA as shown in FIG. 6 in order to minimize or reduce a deviation in the first driving voltage VSS caused by voltage drop (IR drop) or voltage rise (IR rising) of the second electrode CAT in the display area DAA.

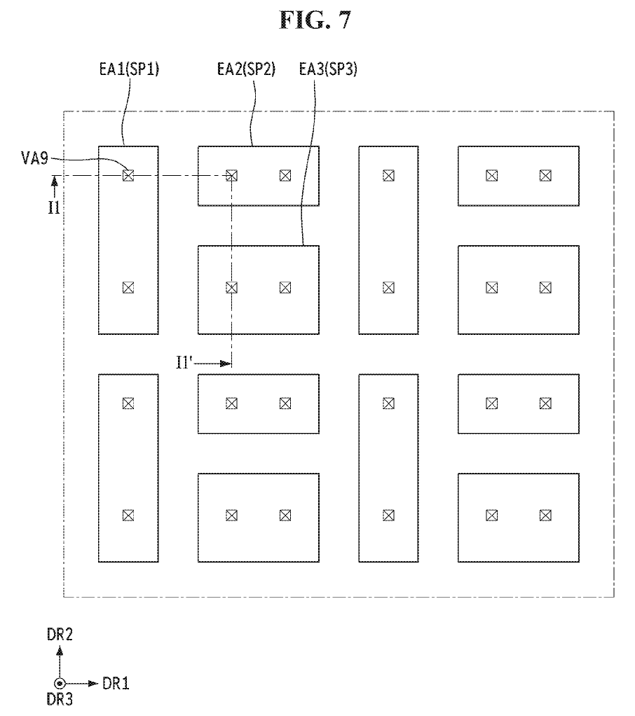

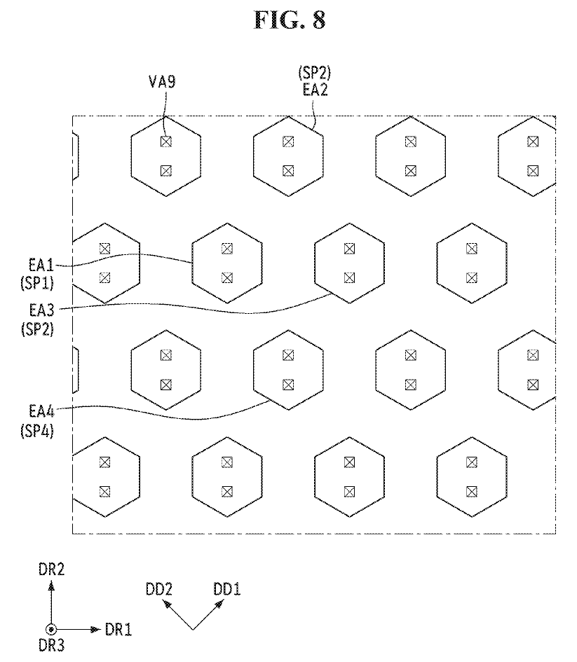

FIG. 7 is a schematic enlarged plan view of a portion of a display area of FIG. 6, according to one or more embodiments of the present disclosure. FIG. 8 is a schematic enlarged plan view of a portion of the display area of FIG. 6, according to one or more embodiments of the present disclosure.

Referring to FIGS. 7 and 8, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 7 and 8, but the present disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In one or more embodiments, the second emission area EA2 and the third emission area EA3 may be adjacent to each other in the second direction DR2. The area of the first emission area EA1, the area of the second emission area EA2, and the area of the third emission area EA3 may be different.

Alternatively, according to one or more embodiments, as shown in FIG. 8, the emission areas EA1, EA2, EA3, and EA4 may each have a hexagonal shape in a plan view. In such embodiments, the first emission area EA1 and the third emission area EA3 may be adjacent in the first direction DR1, and the second emission area EA2 and a fourth emission area EA4 that is an emission area of a fourth sub-pixel SP4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction normal (e.g., perpendicular) to the first diagonal direction DD1.

The first sub-pixel SP1 may be to emit a first light, the second sub-pixel SP2 may be to emit a second light, and the third sub-pixel SP3 may be to emit a third light, and when the fourth sub-pixel SP4 is present, the fourth sub-pixel may be to emit the second light and may have substantially the same structure as the second sub-pixel SP2. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

As shown in FIG. 7, each of the plurality of pixels PX may include three emission areas EA1, EA2, and EA3, or may include four emission areas EA1, EA2, EA3, and EA4 as shown in FIG. 8. In such embodiments, the fourth emission area EA4 may be to emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape. PENTILE^{®} is a duly registered trademark of Samsung Display Co., Ltd.

FIG. 9 is a schematic cross-sectional view of the display panel taken along the line I1-I1' of FIG. 7, according to one or more embodiments of the present disclosure.

Referring to FIG. 9, the display panel 100 includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be arranged on the top surface of the semiconductor substrate SSUB. The plurality of well regions WA may be regions doped with a second type (kind) impurity. The second type (kind) impurity may be different from the first type (kind) impurity. For example, if (e.g., when) the first type (kind) impurity is a p-type (kind) impurity, the second type (kind) impurity may be an n-type (kind) impurity. In one or more embodiments, if (e.g., when) the first type (kind) impurity is an n-type (kind) impurity, the second type (kind) impurity may be a p-type (kind) impurity.

Each of the plurality of well regions WA includes a source region SA corresponding to the source electrode of the pixel transistor PTR, a drain region DA corresponding to the drain electrode thereof, and a channel region CH arranged between the source region SA and the drain region DA.

A lower insulating film BINS may be arranged between a gate electrode GE and the well region WA. A side insulating film SINS may be arranged on the side surface of the gate electrode GE. The side insulating film SINS may be arranged on the lower insulating film BINS.

Each of the source region SA and the drain region DA may be a region doped with the first type (kind) impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be arranged on one side of the gate electrode GE, and the drain region DA may be arranged on the other side of the gate electrode GE.

Each of the plurality of well regions WA further includes a first low-concentration impurity region LDD1 arranged between the channel region CH and the source region SA, and a second low-concentration impurity region LDD2 arranged between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be arranged on the semiconductor substrate SSUB. A second semiconductor insulating film SINS2 may be arranged on the first semiconductor insulating film SINS1.

The plurality of contact terminals CTE may be arranged on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), and/or an alloy including any one or more of them.

A third semiconductor insulating film SINS3 may be arranged on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOₓ)-based inorganic film, but the present disclosure is not limited thereto.

The semiconductor substrate SSUB may be replaced with a glass substrate or a polymer resin substrate such as a polyimide substrate. In such embodiments, thin film transistors may be arranged on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

For example, the first to sixth transistors T1 to T6 may be formed in the semiconductor backplane SBP, and the connection of the first to sixth transistors T1 to T6 and the first and second capacitors CP1 and CP2 is accomplished through the first to eighth conductive layers ML1 to ML8. In one or more embodiments, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one or more of them. The first to eighth vias VA1 to VA8 may be made of substantially the same material. First to eighth interlayer insulating films INS1 to INS8 may be formed of a silicon oxide (SiOₓ)-based inorganic layer, but the present disclosure is not limited thereto.

A ninth interlayer insulating film INS9 may be arranged on the eighth interlayer insulating film INS8 and the eighth conductive layer ML8. The ninth interlayer insulating film INS9 may be formed of a silicon oxide (SiOₓ)-based inorganic film, but the present disclosure is not limited thereto.

Each of the ninth vias VA9 may penetrate the ninth interlayer insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one or more of them.

The display element layer EML may be arranged on the light-emitting element backplane EBP. The display element layer EML may include the tenth and eleventh interlayer insulating films INS10 and INS11, reflective electrodes RL, the first electrodes AND, a light-emitting stack IL, the second electrode CAT, a pixel-defining film PDL, and a plurality of trenches TRC.

The reflective electrodes RL may be arranged on the ninth interlayer insulating film INS9. Each of the reflective electrodes RL may include at least one reflective electrode RL1, RL2, RL3, and/or RL4. For example, each of the reflective electrodes RL may include the first to fourth reflective electrodes RL1, RL2, RL3, and RL4 as shown in FIG. 9.

The first reflective electrodes RL1 may be arranged on the ninth interlayer insulating film INS9, and may be connected to the ninth via VA9. Each of the second reflective electrodes RL2 may be arranged on the first reflective electrode RL1 corresponding thereto. Each of the third reflective electrodes RL3 may be arranged on the second reflective electrode RL2 corresponding thereto. Each of the fourth reflective electrodes RL4 may be arranged on the third reflective electrode RL3 corresponding thereto.

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one or more of them. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be arranged on the ninth interlayer insulating film INS9. The tenth interlayer insulating film INS10 may be arranged between the reflective electrodes RL adjacent to each other. The tenth interlayer insulating film INS10 may be a film for flattening a stepped portion caused by the reflective electrodes RL. The eleventh interlayer insulating film INS11 may be arranged on the tenth interlayer insulating film INS10 and the reflective electrodes RL.

The tenth interlayer insulating film INS10 and the eleventh interlayer insulating film INS11 may be formed of a silicon oxide (SiOₓ)-based inorganic film, but the present disclosure is not limited thereto.

The eleventh interlayer insulating film INS11 may be an optical auxiliary layer for adjusting the resonance distance of light emitted from the light-emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and/or the third sub-pixel SP3. For example, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In such embodiments, the distance between the first electrode AND and the reflective electrode RL in the first sub-pixel SP1 may be greater than the distance between the first electrode AND and the reflective electrode RL in the second sub-pixel SP2. In addition, the distance between the first electrode AND and the reflective electrode RL in the second sub-pixel SP2 may be greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one or more of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be arranged on the eleventh interlayer insulating film INS11 and connected to the tenth via VA10. The first electrode AND of each of the light-emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one or more of them. For example, the first electrode AND of each of the light-emitting elements LE may be titanium nitride (TiN).

The pixel-defining film PDL may be arranged on a part of the first electrode AND of each of the light-emitting elements LE. The pixel-defining film PDL may cover the edge of the first electrode AND of each of the light-emitting elements LE. The pixel-defining film PDL may partition the first emission areas EA1, the second emission areas EA2, and the third emission areas EA3. Each of the first emission area EA1, the second emission area EA2, and the third emission area EA3 may be an area where the light-emitting element LE including the first electrode AND, the light-emitting stack IL, and the second electrode CAT is arranged.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining film PDL may include first to third pixel-defining films PDL1, PDL2, and PDL3. The first pixel-defining film PDL1 may be arranged on the edge of the first electrode AND of each of the light-emitting elements LE, the second pixel-defining film PDL2 may be arranged on the first pixel-defining film PDL1, and the third pixel-defining film PDL3 may be arranged on the second pixel-defining film PDL2. The first pixel-defining film PDL1, the second pixel-defining film PDL2, and the third pixel-defining film PDL3 may be formed of a silicon oxide (SiOₓ)-based inorganic film. Alternatively, in one or more embodiments, the first pixel-defining film PDL1 and the third pixel-defining film PDL3 may be formed of a silicon nitride (SiNₓ)-based inorganic film, whereas the second pixel-defining film PDL2 may be formed of a silicon oxide (SiOₓ)-based inorganic film. The first pixel-defining film PDL1, the second pixel-defining film PDL2, and the third pixel-defining film PDL3 may each have a thickness of about 500 Å.

In order to reduce or prevent or reduce the likelihood of the first encapsulation inorganic film TFE1 being cut off due to the step coverage, the first pixel-defining film PDL1, the second pixel-defining film PDL2, and the third pixel-defining film PDL3 may have a cross-sectional structure having a stepped portion. Step coverage refers to the ratio of the thickness (or amount) of thin film formed on an inclined portion to the thickness (or amount) of thin film formed on a flat portion. The lower the step coverage, the more likely it is that the thin film will be cut off at inclined portions.

Each of the plurality of trenches TRC may penetrate the first pixel-defining film PDL1, the second pixel-defining film PDL2, and the third pixel-defining film PDL3. The eleventh interlayer insulating film INS11 may be at least partially recessed at each of the plurality of trenches TRC.

At least one trench TRC may be arranged between the neighboring sub-pixels SP1, SP2, and SP3. Although FIG. 9 illustrates that two trenches TRC are arranged between the neighboring sub-pixels SP1, SP2, and SP3, the present disclosure is not limited thereto.

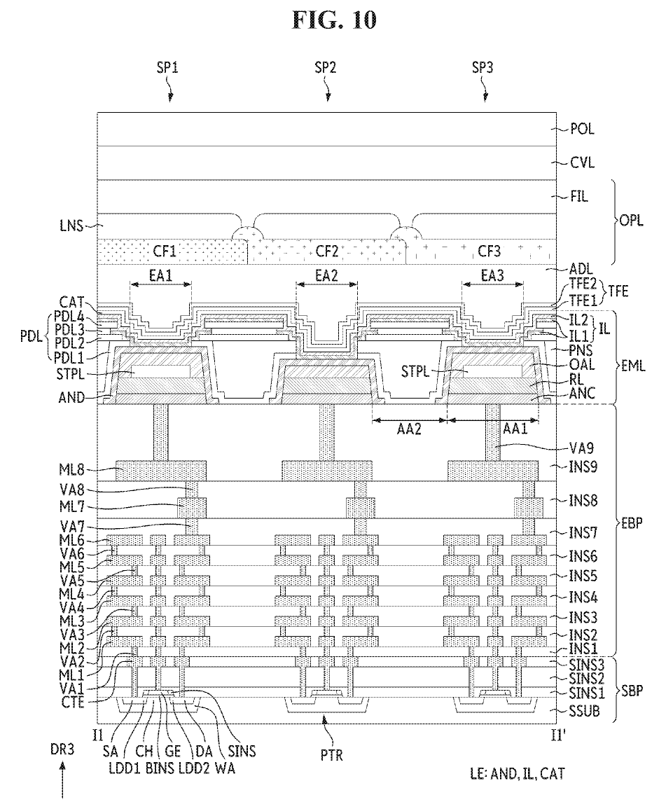

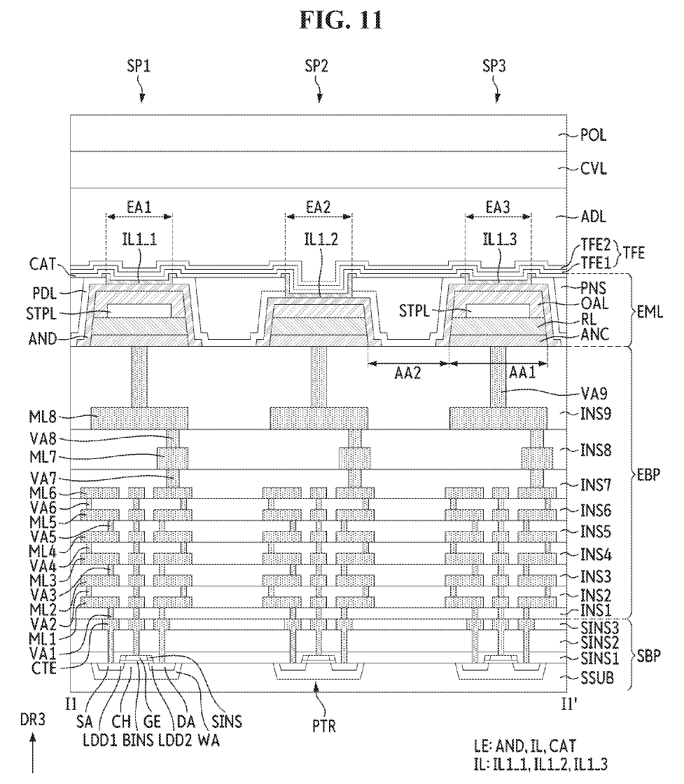

The light-emitting stack IL may include a plurality of stack layers IL1, IL2, and IL3. FIG. 9 illustrates that the light-emitting stack IL has a three-tandem structure including a first stack layer IL1, a second stack layer IL2, and a third stack layer IL3, but the present disclosure is not limited thereto. For example, the light-emitting stack IL may have a two-tandem structure including two stack layers as shown in FIG. 10.

In the three-tandem structure, the light-emitting stack IL may have a tandem structure including a plurality of intermediate layers IL1, IL2, and IL3 that emit different lights. For example, the light-emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light-emitting layer that emits the first light, and a first electron transport layer are sequentially stacked. The second stack layer IL2 may have a structure in which a second hole transport layer, a second light-emitting layer that emits the second light, and a second electron transport layer are sequentially stacked. The third stack layer IL3 may have a structure in which a third hole transport layer, a third light-emitting layer that emits the third light, and a third electron transport layer are sequentially stacked.

A first charge generation layer for supplying charges to the second stack layer IL2 and supplying electrons to the first stack layer IL1 may be arranged between the first stack layer IL1 and the second stack layer IL2. The first charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metal material.

A second charge generation layer for supplying charges to the third stack layer IL3 and supplying electrons to the second stack layer IL2 may be arranged between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be arranged on the first electrodes AND and the pixel-defining film PDL, and a residual film RIL arranged on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be arranged on the first stack layer IL1. Due to the trench TRC, the second stack layer IL2 may be cut off between the neighboring sub-pixels SP1, SP2, and SP3. A cavity ESS or an empty space may be arranged between the residual film IL and the second stack layer IL2 in the trench TRC. The third stack layer IL3 may be arranged on the second stack layer IL2. The third stack layer IL3 may not be cut off by the trench TRC and may be arranged to cover the second stack layer IL2 at (in) each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In one or more embodiments, in the two-tandem structure, each of the plurality of trenches TRC may be a structure for cutting off the charge generation layer and the lower stack layer arranged between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. In order to cut off the charge generation layers and the hole transport layers of the light-emitting stack IL of the display element layer EML between the neighboring sub-pixels SP1, SP2, and SP3, a different structure may be present instead of the trench TRC. For example, instead of the trench TRC, a reverse tapered partition wall may be arranged on the pixel-defining film PDL.

In one or more embodiments, FIG. 9 illustrates that the light-emitting stack IL that emits light is arranged in the first emission area EA1, the second emission area EA2, and the third emission area EA3, but the present disclosure is not limited thereto. For example, instead of the light-emitting stack IL, the first light-emitting layer may be arranged in the first emission area EA1, and may not be provided from the second emission area EA2 and the third emission area EA3. Furthermore, the second light-emitting layer may be arranged in the second emission area EA2 and may not be provided from the first emission area EA1 and the third emission area EA3. Furthermore, the third light-emitting layer may be arranged in the third emission area EA3 and may not be provided from the first emission area EA1 and the second emission area EA2. In such embodiments, first to third color filters CF1, CF2, and CF3 of the optical layer OPL may not be provided.

The second electrode CAT may be arranged on the light-emitting stack IL. For example, the second electrode CAT may be arranged on the third stack layer IL3. The second electrode CAT may be formed of a transparent conductive oxide (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be arranged on the display element layer EML. The encapsulation layer TFE may include at least one inorganic film TFE1 and TFE3 to prevent or reduce the likelihood of oxygen or moisture permeating into the display element layer EML. The first encapsulation inorganic film TFE1 may be arranged on the second electrode CAT, and the second encapsulation inorganic film TFE3 may be arranged above the first encapsulation inorganic film TFE1. The first encapsulation inorganic film TFE1 and/or the second encapsulation inorganic film TFE3 may be formed of multiple layers in which two or more inorganic films of silicon nitride (SiNₓ), silicon oxynitride (SiON), silicon oxide (SiOₓ), titanium oxide (TiOₓ), and/or aluminum oxide (AlOₓ) layers are alternately stacked.

In one or more embodiments, the encapsulation layer TFE may include at least one organic film TFE2 to protect the display element layer EML from foreign substances such as dust. The encapsulating organic film TFE2 may be arranged between the first encapsulating inorganic film TFE1 and the second encapsulating inorganic film TFE3. The encapsulation organic film TFE2 may be a monomer. In one or more embodiments, the encapsulation organic film TFE2 may be an organic film such as acryl resin, epoxy resin, phenolic resin, polyamide resin, polyimide resin and/or the like.

An adhesive layer ADL may be a layer for bonding the encapsulation layer TFE to the optical layer OPL. The adhesive layer ADL may be a double-sided adhesive member. In one or more embodiments, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be arranged on the adhesive layer ADL.

The first color filter CF1 may overlap the first emission area EA1 of the first sub-pixel SP1. The first color filter CF1 may be to transmit light of the first color, i.e., light of a blue wavelength band. The blue wavelength band may be about 370 nm to about 460 nm. Thus, the first color filter CF1 may be to transmit light of the first color among light emitted from the first emission area EA1.

The second color filter CF2 may overlap the second emission area EA2 of the second sub-pixel SP2. The second color filter CF2 may be to transmit light of the second color, i.e., light of a green wavelength band. The green wavelength band may be about 480 nm to about 560 nm. Thus, the second color filter CF2 may be to transmit light of the second color among light emitted from the second emission area EA2.

The third color filter CF3 may overlap the third emission area EA3 of the third sub-pixel SP3. The third color filter CF3 may be to transmit light of the third color, i.e., light of a red wavelength band. The red wavelength band may be about 600 nm to about 750 nm. Thus, the third color filter CF3 may be to transmit light of the third color among light emitted from the third emission area EA3.

The plurality of lenses LNS may be arranged on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be arranged on the plurality of lenses LNS. The filling layer FIL may have a set or predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be arranged on the filling layer FIL. The cover layer CVL may be a glass substrate or a polymer resin. When the cover layer CVL is a glass substrate, it may be attached onto the filling layer FIL. In such embodiments, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be arranged on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, if (e.g., when) visibility degradation caused by reflection of external light is sufficiently overcome by the first to third color filters CF1, CF2, and CF3, the polarizing plate may not be provided.

FIG. 10 is a schematic cross-sectional view of the display panel taken along the line I1-I1' of FIG. 7, according to one or more embodiments of the present disclosure.

The embodiment of FIG. 10 differs from the embodiments of FIG. 9 in that the first electrode AND of each of the light-emitting elements LE is in contact with and electrically connected to the side surface of a connection electrode ANC connected to the eighth conductive layer ML8. The embodiment of FIG. 10 also differs from the one or more embodiments of FIG. 9 in that the trench TRC is omitted, and instead, the third pixel-defining film PDL3 and a fourth pixel-defining film PDL4 have an eave-shaped or mushroom-shaped cross-sectional structure. In the one or more embodiments of FIG. 10, redundant description of parts already described with reference to FIG. 9 may not be provided.

Referring to FIG. 10, the plurality of connection electrodes ANC may be respectively arranged on first portions AA1 of the ninth interlayer insulating film INS9. Each of the plurality of connection electrodes ANC may be arranged on the first portion AA1 of the ninth interlayer insulating film INS9 corresponding thereto. The plurality of connection electrodes ANC may be formed of any one of copper (Cu), aluminum (Al), tungsten (W), molybdenum (Mo), chromium (Cr), gold (Au), titanium (Ti), nickel (Ni), and/or neodymium (Nd), an alloy including any one or more of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively arranged on the plurality of connection electrodes ANC. Each of the plurality of reflective electrodes RL may be arranged on the connection electrode ANC corresponding thereto. The plurality of reflective electrodes RL may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one or more of them. For example, each of the plurality of reflective electrodes RL may include aluminum (Al) having high reflectivity.

A plurality of optical auxiliary films OAL may be respectively arranged on the plurality of reflective electrodes RL. Each of the plurality of optical auxiliary films OAL may be arranged on the reflective electrode RL corresponding thereto. The plurality of optical auxiliary films OAL may be formed of a silicon oxide (SiOₓ)-based inorganic film, but the present disclosure is not limited thereto.

In each of the first emission area EA1 and the third emission area EA3, a step layer STPL may be arranged on the reflective electrode RL, and the optical auxiliary film OAL may be arranged on the step layer STPL. In the second emission area EA2, only the optical auxiliary film OAL may be arranged on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light-emitting stack IL, and the wavelength and resonance distance of light emitted from the second stack layer IL2 thereof.

Each of the light-emitting elements LE may include the first electrode AND, a light-emitting stack IL, and a second electrode CAT.

The first electrode AND of each of the light-emitting elements LE may be arranged on the optical auxiliary film OAL corresponding thereto. Because the connection electrode ANC, the reflective electrode RL, and the optical auxiliary layer OAL are sequentially stacked, the first electrode AND of each of the light-emitting elements LE may be arranged on the top surface and the side surface of the optical auxiliary layer OAL, the side surface of the reflective electrode RL, and the side surface of the connection electrode ANC. Accordingly, the first electrode AND of each of the light-emitting elements LE may be in contact with and electrically connected to the side surface of the reflective electrode RL and the side surface of the connection electrode ANC. Therefore, compared to when the first electrode AND of each of the light-emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

Alternatively, in one or more embodiments, the thickness of the first portion AA1 of the ninth interlayer insulating film INS9 may be greater than the thickness of the second portion AA2 thereof. In such embodiments, the side surface of the first portion AA1 of the ninth interlayer insulating film INS9 may be exposed, and the first electrode AND of each of the light-emitting elements LE may be arranged on the exposed side surface of the first portion AA1 of the ninth interlayer insulating film INS9.

The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and/or neodymium (Nd), an alloy including any one or more of them, or a transparent conductive oxide. For example, the first electrode AND of each of the light-emitting elements LE may include titanium (Ti), titanium nitride (TiN), indium tin oxide (ITO), or indium zinc oxide (IZO), but the present disclosure is limited thereto.

The pixel-defining film PDL may be arranged on a part of the first electrode AND of each of the light-emitting elements LE. The pixel-defining film PDL may cover the edge of the first electrode AND of each of the light-emitting elements LE. The pixel-defining film PDL may partition the first emission areas EA1, the second emission areas EA2, and the third emission areas EA3.

The pixel-defining film PDL may include first to fourth pixel-defining films PDL1, PDL2, PDL3, and PDL4.

The first pixel-defining film PDL1 may be arranged on the first electrode AND of each of the light-emitting elements LE. For example, the first pixel-defining film PDL1 may cover a part of the top surface of the first electrode AND arranged on the optical auxiliary film OAL. Further, the first pixel-defining film PDL1 may cover the first electrode AND arranged on the side surface of the connection electrode ANC, the side surface of the reflective electrode RL, and the side surface of the optical auxiliary film OAL. The first pixel-defining film PDL1 may be arranged on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be arranged on the first pixel-defining film PDL1 covering the first electrode AND arranged on the side surface of the connection electrode ANC, the side surface of the reflective electrode RL, and the side surface of the optical auxiliary film OAL. The planarization film PNS may be arranged on the first pixel-defining film PDL1 arranged on the second portion AA2 of the ninth interlayer insulating film INS9.

The planarization film PNS may be arranged between the connection electrodes ANC adjacent in the first direction DR1 or the second direction DR2. The planarization film PNS may be arranged between the reflective electrodes RL adjacent in the first direction DR1 or the second direction DR2. The planarization film PNS may be arranged between the optical auxiliary films OAL adjacent in the first direction DR1 or the second direction DR2.

The step layer STPL may not be present in the second emission area EA2, whereas the step layer STPL may be present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel-defining film PDL1 arranged on the top surface of the first electrode AND arranged in the second emission area EA2.

In contrast, the top surface of the planarization film PNS may be flatly connected to the top surface of the first pixel-defining film PDL1 arranged on the top surface of the first electrode AND arranged in the first emission area EA1 and the third emission area EA3. For example, the planarization film PNS may not cover the top surface of the first pixel-defining film PDL1 arranged on the top surface of the first electrode AND arranged in each of the first emission area EA1 and the third emission area EA3.

The second pixel-defining film PDL2 may be arranged on the first pixel-defining film PDL1 and the planarization film PNS, the third pixel-defining film PDL3 may be arranged on the second pixel-defining film PDL2, and the fourth pixel-defining film PDL4 may be arranged on the third pixel-defining film PDL3. The first pixel-defining film PDL1 and the third pixel-defining film PDL3 may be formed of a silicon nitride (SiNₓ)-based inorganic film, whereas the second pixel-defining film PDL2, the fourth pixel-defining film PDL4, and the planarization film PNS may be formed of a silicon oxide (SiOₓ)-based inorganic film. The first pixel-defining film PDL1 is formed of a material different from that of the planarization film PNS, and thus may serve as a stopper in a chemical mechanical polishing process for the planarization film PNS.

When the planarization film PNS and the second pixel-defining film PDL2 are both formed as a silicon oxide (SiOₓ)-based inorganic film, the planarization film PNS and the second pixel-defining film PDL2 may be formed as a single film.

Because the length of the third pixel-defining film PDL3 in one direction is less than the length of the fourth pixel-defining film PDL4 in one direction, the bottom surface of the fourth pixel-defining film PDL4 may be exposed without being covered by the third pixel-defining film PDL3. For example, the third pixel-defining film PDL3 and the fourth pixel-defining film PDL4 may have an eaves-shaped or mushroom-shaped cross-sectional structure.

The light-emitting stack IL may be arranged on the first electrode AND and the pixel-defining film PDL. The light-emitting stack IL may include the first stack layer IL1 and the second stack layer IL2 that emit different lights. When the light-emitting stack IL has a two-tandem structure, one of the first stack layer IL1 and the second stack layer IL2 may be to emit light that includes the wavelength range of any one of the first light, the second light, and the third light, and the other may be to emit light that includes the wavelength ranges of the other two lights. For example, the first stack layer IL1 may be to emit light that includes the wavelength range of the first light and the wavelength range of the third light, and the second stack layer IL2 may be to emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be arranged between the first stack layer IL1 and the second stack layer IL2. The charge generation layer may include an n-type (kind) charge generation layer that supplies electrons to the first stack layer IL1 and a p-type (kind) charge generation layer that supplies holes to the second stack layer IL2. The N-type (kind) charge generation layer may include a dopant of a metal material.

The first stack layer IL1 is not formed on the bottom surface of the fourth pixel-defining film PDL4 that is exposed without being covered by the third pixel-defining film PDL3, and thus may be cut off by the eaves-shaped or mushroom-shaped cross-sectional structure of the third pixel-defining film PDL3 and the fourth pixel-defining film PDL4. In such embodiments, the first hole transport layer of the first stack layer IL1, and a charge generation layer arranged between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent or reduce a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent or reduce the likelihood of the light-emitting stack IL in the adjacent emission areas EA1, EA2, and EA3 from emitting light other than the originally intended light due to the influence of the above current.

Although FIG. 10 illustrates a two-tandem structure in which the light-emitting stack IL includes two stack layers IL1 and IL2, the present disclosure is not limited thereto. For example, the light-emitting stack IL may have a three-tandem structure including three stack layers as shown in FIG. 9. In such embodiments, it may be designed such that the charge generation layer between the first stack layer IL1 and the second stack layer IL2, and the charge generation layer between the second stack layer IL2 and the third stack layer IL3 are cut off by adjusting the height of the third pixel-defining film PDL3. Alternatively, in one or more embodiments, as shown in FIG. 9, the trench TRC penetrating the first pixel-defining film PDL1, the planarization film PNS, the second pixel-defining film PDL2, and the third pixel-defining film PDL3 may be added. In such embodiments, the trench TRC may penetrate at least a part of the ninth interlayer insulating film INS9, but the present disclosure is not limited thereto.

FIG. 11 is a schematic cross-sectional view of the display panel taken along the line I1-I1' of FIG. 7, according to one or more embodiments of the present disclosure.

The embodiment of FIG. 11 differs from one or more embodiments of FIG. 10 in that the light-emitting elements LE have a single stack structure. In the one or more embodiments of FIG. 11, redundant description of parts already described with reference to FIG. 10 may not be provided.

Referring to FIG. 11, the pixel-defining film PDL may be arranged on the ninth interlayer insulating film INS9 and the first electrodes AND, and the planarization film PNS may be arranged on the pixel-defining film PDL. The planarization film PNS and the pixel-defining film PDL may have openings exposing the first electrodes AND, and light-emitting stack IL may be arranged on the first electrodes AND. For example, the pixel-defining film PDL may have openings exposing the first electrodes AND in the first light emission area EA1, the second light emission area EA2 and the third light emission area EA3, and the planarization film PNS may have an opening exposing the first electrode AND in the second light emission area EA2. The first electrodes AND may be exposed by the planarization film PNS in the first light emission area EA1 and the third light emission area EA3 because the height of the planarization film PNS in the third direction DR3 may not be tall enough to cover the top surface of the first electrodes AND in the first light emission area EA1 and the third light emission area EA3.

For example, the light-emitting stack IL may include a first stack layer IL1_1, a second stack layer IL1_2, and a third stack layer IL1_3.

The first stack layer IL1_1 may be arranged on the first electrode AND exposed by the pixel-defining film PDL in the first light emission area EA1. The first stack layer IL1_1 may also be arranged on a portion of the pixel-defining film PDL. For example, the first stack layer IL1_1 may include a hole injecting layer, a hole transporting layer, a first light-emitting layer, an electron transporting layer, and an electron injecting layer.

The second stack layer IL1_2 may be arranged on the first electrode AND exposed by the planarization film PNS and the pixel-defining film PDL in the second light emission area EA2. The second stack layer IL1_2 may also be arranged on a portion of the planarization film PNS. For example, the second stack layer IL1_2 may include the hole injecting layer, the hole transporting layer, a second light-emitting layer, the electron transporting layer, and the electron injecting layer.

The third stack layer IL1_3 may be arranged on the first electrode AND exposed by the pixel-defining film PDL in the third light emission area EA3. The third stack layer IL1_3 may also be arranged on a portion of the pixel-defining film PDL. For example, the third stack layer IL1_3 may include the hole injecting layer, the hole transporting layer, a third light-emitting layer, the electron transporting layer, and the electron injecting layer.

The first stack layer IL1_1, the second stack layer IL1_2, and the third stack layer IL1_3 may be spaced and/or apart (e.g., spaced apart or separated) from each other, and thus the second to fourth pixel-defining films PDL2, PDL3 and PDL4 used to separate the light-emitting stack IL in one or more embodiments of FIG. 10 may not be provided.

The first stack IL1_1 of the first light emission area EA1 may be to emit the first light, the second stack layer IL1_2 of the second light emission area EA2 may be to emit the second light, and the third stack layer IL1_3 of the third light emission area EA3 may be to emit the third light. Accordingly, the first to third color filters CF1, CF2 and CF3 of the optical layer OPL used in the one or more embodiments of FIG. 9, the plurality of lenses LNS, and the filling layer FIL may not be provided.

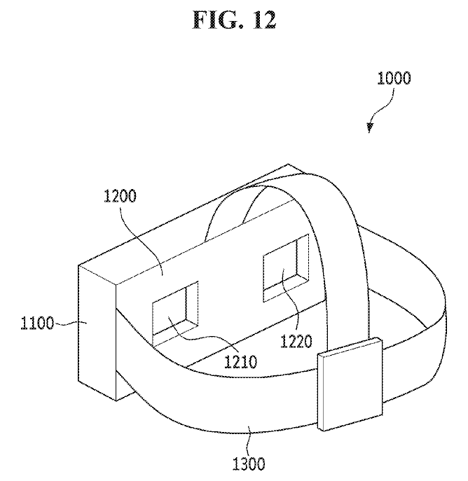

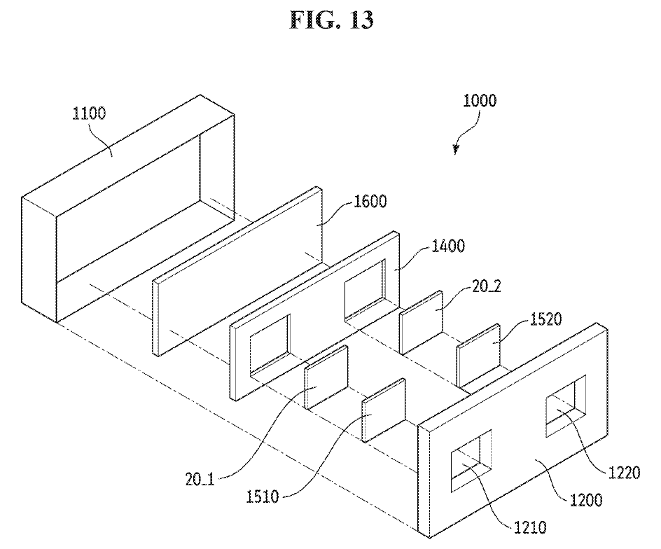

FIG. 12 is a schematic perspective view illustrating a head mounted display, according to one or more embodiments of the present disclosure. FIG. 13 is a schematic exploded perspective view of the head mounted display of FIG. 12, according to one or more embodiments of the present disclosure.

Referring to FIGS. 12 and 13, a head mounted display 1000 according to one or more embodiments includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Because each of the first display device 20_1 and the second display device 20_2 is substantially the same as the display device 20 described in conjunction with FIGS. 3 - 11, the description of the first display device 20_1 and the second display device 20_2 may not be provided.

The first optical member 1510 may be arranged between the first display device 20_1 and the first eyepiece 1210. The second optical member 1520 may be arranged between the second display device 20_2 and the second eyepiece 1220. Each of the first optical member 1510 and the second optical member 1520 may include at least one convex lens.

The middle frame 1400 may be arranged between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be arranged between the middle frame 1400 and the display device housing 1100. The control circuit board 1600 may be connected to the first display device 20_1 and the second display device 20_2 through a connector. The control circuit board 1600 may convert an image source inputted from the outside into the digital video data DATA, and transmit the digital video data DATA to the first display device 20_1 and the second display device 20_2 through the connector.

The control circuit board 1600 may be to transmit the digital video data DATA corresponding to a left-eye image improved or optimized for the user's left eye to the first display device 20_1, and may be to transmit the digital video data DATA corresponding to a right-eye image improved or optimized for the user's right eye to the second display device 20_2. Alternatively, in one or more embodiments, the control circuit board 1600 may be to transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye is located and the second eyepiece 1220 at which the user's right eye is located. FIGS. 12 and 13 illustrate that the first eyepiece 1210 and the second eyepiece 1220 are arranged separately, but the present disclosure is not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

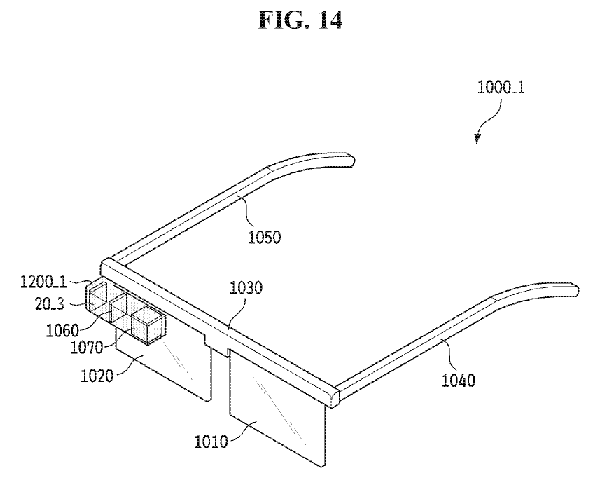

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 14, an eyeglass frame instead of the head mounted band 1300.

FIG. 14 is a schematic perspective view of a head mounted display, according to one or more embodiments of the present disclosure.

Referring to FIG. 14, a head mounted display 1000_1 according to one or more embodiments may be an eyeglasses-type (kind) display device in which a display device housing 1200_1 is implemented in a lightweight and compact manner. The head mounted display 1000_1 according to one or more embodiments may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 14 illustrates that the display device housing 1200_1 is arranged at the right end of the support frame 1030, but the present disclosure is not limited thereto. For example, the display device housing 1200_1 may be arranged at the left end of the support frame 1030, and in such embodiments, the image of the display device 20_3 may be provided to the user's left eye. Alternatively, in one or more embodiments, the display device housing 1200_1 may be arranged at both the left and right ends of the support frame 1030, and in such embodiments, the user may view the image displayed on the display device 20_3 through both the left and right eyes.

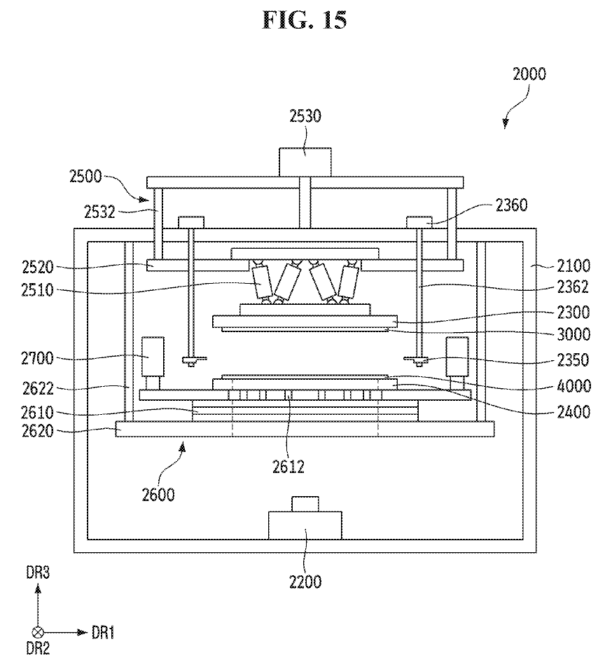

FIG. 15 is a schematic diagram illustrating a deposition mask and a deposition apparatus including the deposition mask according to one or more embodiments of the present disclosure.

Referring to FIG. 15, a deposition apparatus 2000 according to one or more embodiments may be used to form a deposition material layer on a substrate. For example, the deposition apparatus 2000 according to one or more embodiments may be used to form light-emitting layers on a backplane substrate 3000 (or display substrate) in a manufacturing process of the display panel 100 (see, e.g., FIG. 3). For example, as shown in FIG. 11, the semiconductor backplane SBP and the light-emitting element backplane EBP may be located on the backplane substrate 3000, and electrode patterns, e.g., the first electrodes AND functioning as anode electrodes, may be located on the light-emitting element backplane EBP. In one or more embodiments, the pixel-defining film PDL having openings that expose the first electrodes AND may be located on the light-emitting element backplane EBP. As an example, the deposition apparatus 2000 may form first light-emitting layers on the first electrodes AND of the first emission areas EA1. The deposition apparatus 2000 may form second light-emitting layers on the first electrodes AND of the second emission areas EA2. The deposition apparatus 2000 may form third light-emitting layers on the first electrodes AND of the third emission areas EA3.

The deposition apparatus 2000 may include a deposition source 2200 for providing a vapor deposition material on the backplane substrate 3000, a substrate chuck 2300 for supporting the backplane substrate 3000 to face the deposition source 2200, and a mask chuck 2400 located between the deposition source 2200 and the substrate chuck 2300 to support a deposition mask 4000 to face the backplane substrate 3000. The deposition source 2200, the substrate chuck 2300, and the mask chuck 2400 may be located in a process chamber (or an evaporation chamber) 2100.

A process chamber 2100 may have an internal space, and a deposition process for forming a deposition material layer on the backplane substrate 3000 may be performed in the internal space of the process chamber 2100. The process chamber 2100 may be connected to a vacuum pump, and a vacuum atmosphere may be created in the internal space of the process chamber 2100 by the vacuum pump. An opening for loading/unloading of the backplane substrate 3000 and the deposition mask 4000 may be provided on one wall of the process chamber 2100, and the opening may be opened and closed by a gate valve.

The deposition source 2200 may be located in the process chamber 2100, and a deposition material may be stored in the deposition source 2200. The deposition source 2200 may evaporate a deposition material such as an organic material, an inorganic material, a conductive material, and/or the like toward the backplane substrate 3000, and the evaporated deposition material may be deposited on the backplane substrate 3000 through the deposition mask 4000. For example, the deposition source 2200 may evaporate an organic light-emitting material for forming light-emitting layers on the backplane substrate 3000, and may be provided with a heater for evaporating the organic light-emitting material. The evaporated organic light-emitting material may be deposited on electrode patterns on the backplane substrate 3000 through the deposition mask 4000, thereby forming light-emitting layers on the electrode patterns of the backplane substrate 3000. As shown in FIG. 15, the deposition source 2200 may be located on the central portion of the bottom surface of the process chamber 2100, but the deposition source 2200 may be configured to move horizontally by a separate driver.

The substrate chuck 2300 may be located above the deposition source 2200 and may support the backplane substrate 3000 such that the backplane substrate 3000 faces the deposition source 2200. For example, the substrate chuck 2300 may be an electrostatic chuck that holds the rear surface of the backplane substrate 3000 using an electrostatic force. For example, the electrode patterns, e.g., first electrodes AND, may be located on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. For example, three or four lift fingers 2350 may be arranged around the substrate chuck 2300 and the mask chuck 2400, and may be moved in the third direction DR3 by the finger drivers 2360.

The backplane substrate 3000 may be loaded into the process chamber 2100 by a transfer robot, and may be transferred from the transfer robot onto the lift fingers 2350 under the substrate chuck 2300. In such embodiments, the rear surface of the backplane substrate 3000 may face the bottom surface of the substrate chuck 2300, and the lift fingers 2350 may support the front edge portions of the backplane substrate 3000. The finger drivers 2360 may raise the lift fingers 2350 such that the backplane substrate 3000 becomes adjacent to the bottom surface of the substrate chuck 2300, and the rear surface of the backplane substrate 3000 may be held on the bottom surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In one or more embodiments, the finger drivers 2360 may rotate the lift fingers 2350 with respect to each of the driving shafts 2362. For example, the finger drivers 2360 may rotate the lift fingers 2350 such that the ends of the lift fingers 2350 do not overlap the substrate chuck 2300 and the mask chuck 2400, thereby enabling vertical movement of the lift fingers 2350. In one or more embodiments, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2400. In such embodiments, recesses into which ends of lift fingers 2350 are inserted may be provided at the edge portions of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. For example, the mask chuck 2400 may be an electrostatic chuck configured to hold the edge portion of the deposition mask 4000 using an electrostatic force. In particular, the mask chuck 2400 may have a circular opening to expose the deposition mask 4000 toward the deposition source 2200. For example, the mask chuck 2400 may have a disk shape or a quadrilateral plate shape with a circular opening.

The deposition apparatus 2000 may include a chuck driver for adjusting the position and angle of the backplane substrate 3000 and the deposition mask 4000. For example, the deposition apparatus 2000 may include a substrate chuck driver 2500 for moving the substrate chuck 2300 and a mask chuck driver 2600 for moving the mask chuck 2400.

The substrate chuck driver 2500 may move the substrate chuck 2300 in the first direction DR1, the second direction DR2, and the third direction DR3 to adjust the position of the backplane substrate 3000. In such embodiments, the first direction DR1 may be the first horizontal direction, the second direction DR2 may be the second horizontal direction normal (e.g., perpendicular) to the first direction DR1, and the third direction DR3 may be the vertical direction. For example, the first direction DR1, the second direction DR2, and the third direction DR3 may be an X-axis direction, a Y-axis direction, and a Z-axis direction, respectively.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis in order to adjust the inclination of the backplane substrate 3000. For example, the substrate chuck driver 2500 may include a hexapod actuator 2510 that provides a motion of six degrees of freedom (X, Y, Z, θx, θy, and θz).

The substrate chuck driver 2500 may include a substrate stage 2520 to (on) which the hexapod actuator 2510 is mounted, and a second actuator 2530 connected to the substrate stage 2520. The substrate stage 2520 may be located horizontally in the process chamber 2100, and the second actuator 2530 may be located above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. For example, the second actuator 2530 may be configured using a brushless DC motor, a linear motor, a direct drive (DD) motor, and/or the like, and may adjust the height of the substrate chuck 2300 for loading or unloading the backplane substrate 3000.

The hexapod actuator 2510 may include a first platform connected to the substrate chuck 2300, a second platform mounted to (on) the substrate stage 2520, and six sub-actuators located between the first platform and the second platform. For example, the six sub-actuators may each be configured using a brushless DC motor, a voice coil linear motor, a step motor, a direct drive (DD) motor, a servo motor, and/or the like, and may move and rotate the first platform to adjust the horizontal position, vertical position, azimuth, and inclination of the backplane substrate 3000.

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to the central axis of the mask chuck 2400. For example, the mask chuck driver 2600 may move the mask chuck 2400 in the first direction DR1 (X-axis) and the second direction DR2 (Y-axis), and may rotate the mask chuck 2400 with respect to the third direction DR3 (Z-axis).

The mask chuck driver 2600 may include, e.g., a piezo actuator 2610 that provides a motion of three degrees of freedom (X, Y, and θz). The piezo actuator 2610 may have an opening communicating with the circular opening of the mask chuck 2400. The mask chuck 2400 may be spaced upward from the piezo actuator 2610 by a selected distance. For example, a plurality of support members 2612 may be arranged on the piezo actuator 2610, and the mask chuck 2400 may be located on the plurality of support members 2612.

The mask chuck driver 2600 may include a mask stage 2620 that is horizontally located in the process chamber 2100 and supports the piezo actuator 2610. For example, the mask stage 2620 may have an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may lower the substrate chuck 2300 such that the backplane substrate 3000 is brought adjacent to the deposition mask 4000. The hexapod actuator 2510 may adjust the gap between the backplane substrate 3000 and the deposition mask 4000, and may adjust the inclination of the substrate chuck 2300 to adjust the parallelism between the substrate chuck 2300 and the mask chuck 2400. For example, a plurality of gap sensors for measuring the gap between the substrate chuck 2300 and the mask chuck 2400 may be mounted at (on) the substrate chuck 2300, and the hexapod actuator 2510 may adjust the parallelism between the substrate chuck 2300 and the mask chuck 2400 based on the measured values of the gap sensors.

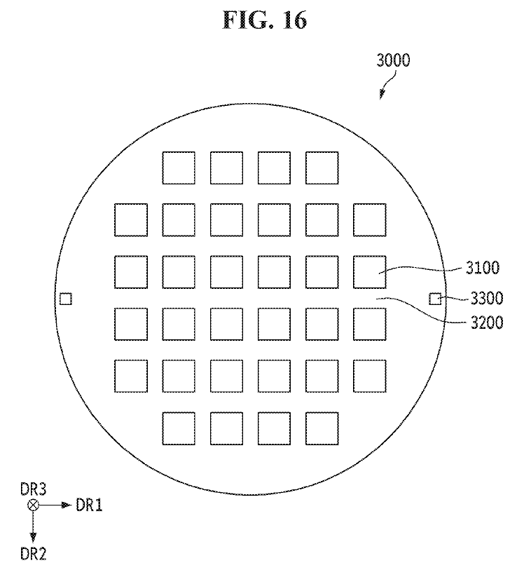

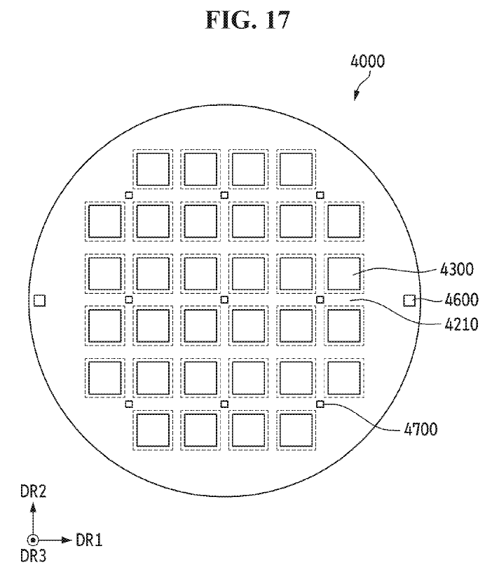

The deposition apparatus 2000 may include cameras 2700 for acquiring positional information of the backplane substrate 3000 and the deposition mask 4000 for alignment between the backplane substrate 3000 and the deposition mask 4000. For example, substrate alignment keys 3300 (see, e.g., FIG. 16) may be arranged on the edge portions of the backplane substrate 3000, and mask alignment keys 4600 (see, e.g., FIG. 17) may be arranged on the edge portions of the deposition mask 4000. The deposition apparatus 2000 may include the cameras 2700 for detecting the substrate alignment keys 3300 and the mask alignment keys 4600, and the substrate chuck driver 2500 or the mask chuck driver 2600 may align the backplane substrate 3000 and the deposition mask 4000 with each other based on the positional information of the substrate alignment keys 3300 and the mask alignment keys 4600 obtained by the cameras 2700.

As described above, after the parallelism adjustment between the substrate chuck 2300 and the mask chuck 2400 and the positional alignment between the backplane substrate 3000 and the deposition mask 4000 are performed, the backplane substrate 3000 may be positioned on the deposition mask 4000. For example, the hexapod actuator 2510 may adjust the height of the substrate chuck 2300 such that the gap between the backplane substrate 3000 and the deposition mask 4000 becomes a selected gap, e.g., a gap of several μm. For another example, the hexapod actuator 2510 may adjust the height of the substrate chuck 2300 such that the backplane substrate 3000 is brought into contact with the deposition mask 4000.

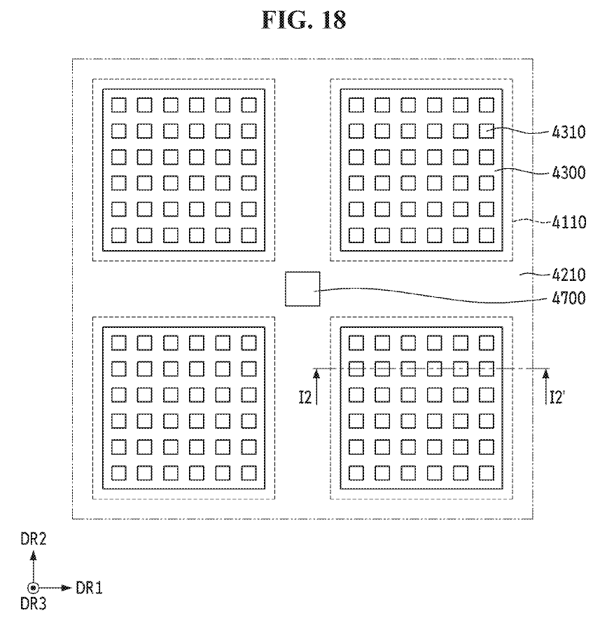

After the backplane substrate 3000 is positioned on the deposition mask 4000, the deposition source 2200 may provide a vapor deposition material onto the backplane substrate 3000 through the deposition mask 4000, thereby forming a deposition material layer on the backplane substrate 3000. For example, the deposition source 2200 may provide a vapor light-emitting material for forming light-emitting layers on the backplane substrate 3000, and the vapor light-emitting material may be deposited on the electrode patterns of the backplane substrate 3000 through pixel openings 4310 (see, e.g., FIG. 18) of the deposition mask 4000.

FIG. 16 is a schematic bottom view illustrating the backplane substrate of FIG. 15, according to one or more embodiments of the present disclosure.

Referring to FIG. 16, the backplane substrate 3000 may include a plurality of display cell regions 3100 and a scribe lane region 3200 located between the display cell regions 3100. The display cell regions 3100 may be arranged in a matrix form along the first direction DR1 and the second direction DR2 as illustrated in FIG. 16, and may be individualized into the display panels 100 (see, e.g., FIG. 3) by a dicing process after the display manufacturing process is completed (e.g., the display cell regions 3100 may be divided into individual display panels 100 by a dicing process after the display manufacturing process is completed). For example, the first direction DR1 may be a first horizontal direction, and the second direction DR2 may be a second horizontal direction normal (e.g., perpendicular) to the first direction DR1. In one or more embodiments, each of the display cell regions 3100 may have, for example, a quadrilateral shape as shown in the drawing.

For example, each of the display cell regions 3100 may include the semiconductor backplane SBP and the light-emitting element backplane EBP located on the semiconductor backplane SBP, as shown in FIG. 11. In one or more embodiments, a plurality of electrode patterns, e.g., the plurality of first electrodes AND may be located on the light-emitting element backplane EBP, and the pixel-defining film PDL having openings that expose the first electrodes AND may be located on the light-emitting element backplane EBP and the first electrodes AND. In such embodiments, the electrode patterns of the display cell regions 3100 may be arranged on the front surface of the backplane substrate 3000, and the substrate chuck 2300 may hold the rear surface of the backplane substrate 3000 such that the electrode patterns of the display cell regions 3100 face downward, i.e., face the deposition source 2200.

According to one or more embodiments, the backplane substrate 3000 may include the substrate alignment keys 3300. For example, the substrate alignment keys 3300 may be located on one or more edge portions of the backplane substrate 3000, and may be used for positional alignment between the backplane substrate 3000 and the deposition mask 4000. As shown in FIG. 16, two substrate alignment keys 3300 are used, but the number of substrate alignment keys 3300 may be variously changed, and the scope of the present disclosure is not limited to a particular number of substrate alignment keys 3300.

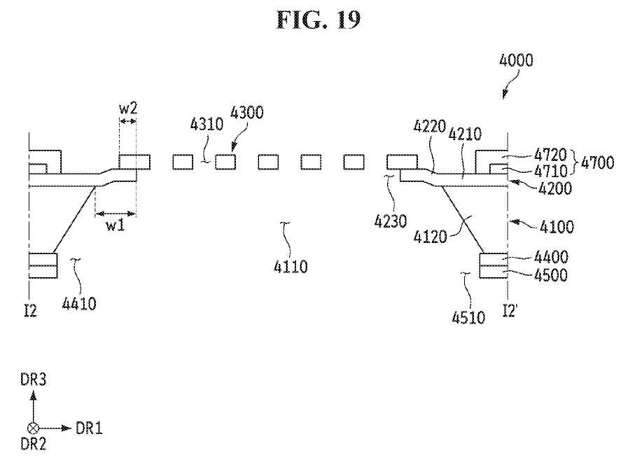

FIG. 17 is a schematic plan view illustrating the deposition mask of FIG. 15, according to one or more embodiments of the present disclosure. FIG. 18 is a schematic plan view illustrating membranes shown in FIG. 17, according to one or more embodiments of the present disclosure. FIG. 19 is a schematic cross-sectional view taken along the line I2-I2' of FIG. 18, according to one or more embodiments of the present disclosure.

Referring to FIGS. 17 - 19, the deposition mask 4000 may include membranes 4300 respectively corresponding to the display cell regions 3100 of the backplane substrate 3000, and a grid region 4210 corresponding to the scribe lane region 3200 of the backplane substrate 3000. Each of the membranes 4300 may have a plurality of pixel openings 4310 exposing the electrode patterns of the backplane substrate 3000 in a deposition process. For example, if (e.g., when) the backplane substrate 3000 is positioned on (e.g., above) the deposition mask 4000 in the deposition process, the electrode patterns, e.g., the first electrodes AND, of the backplane substrate 3000 may be positioned on (e.g., above) the pixel openings 4310 of the deposition mask 4000, and accordingly, the first electrodes AND may be exposed toward the deposition source 2200 through the pixel openings 4310.

According to one or more embodiments, the deposition mask 4000 may include a mask substrate 4100, a buffer inorganic film 4200 located on the mask substrate 4100, and membranes 4300 located on the buffer inorganic film 4200.

According to one or more embodiments, the mask substrate 4100 may have cell openings 4110 respectively corresponding to the display cell regions 3100 of the backplane substrate 3000. For example, the cell openings 4110 may be formed to penetrate the mask substrate 4100, and the mask substrate 4100 may include a rib region 4120 defining the cell openings 4110. According to one or more embodiments, the mask substrate 4100 may include single crystal silicon. For example, a single crystal silicon substrate having a thickness in a range of about 700 μm to about 800 μm, e.g., about 725 μm or about 775 μm, may be used as the mask substrate 4100.

According to one or more embodiments, the buffer inorganic film 4200 may include the grid region 4210 located on the rib region 4120 of the mask substrate 4100, and eaves regions 4220 exposed by the cell openings 4110. For example, in plan view, the eaves regions 4220 may extend from the grid region 4210 in the first direction DR1 and the second direction DR2, and may have a ring shape with a constant width. For example, the eaves regions 4220 may have an approximately quadrilateral ring shape, and may define buffer openings 4230 that are connected to the cell openings 4110.

According to one or more embodiments, the membranes 4300 may be respectively located on the eaves regions 4220 of the buffer inorganic film 4200, and each of the membranes 4300 may have the plurality of pixel openings 4310. The pixel openings 4310 may be formed to penetrate the membranes 4300, and may be connected to the cell openings 4110 through the buffer openings 4230. For example, the portions of the membranes 4300 where the pixel openings 4310 are formed may be exposed by the buffer openings 4230, and the edge portions of the membranes 4300 may be positioned on the eaves regions 4220 of the buffer inorganic film 4200.

According to one or more embodiments, as illustrated, e.g., in FIGS. 17 and 18, each of the membranes 4300 may have a quadrilateral plate shape. However, the shapes of the cell openings 4110 of the mask substrate 4100, the eaves regions 4220, the buffer openings 4230 of the buffer inorganic film 4200, and the membranes 4300 may vary according to the shape of the display cell regions 3100 of the backplane substrate 3000, and thus the scope of the present disclosure is not limited to a particular shape.

According to one or more embodiments, if (e.g., when) the backplane substrate 3000 is located on the deposition mask 4000 in the deposition process, the membranes 4300 may face the display cell regions 3100, and the grid region 4210 of the buffer inorganic film 4200 may face the scribe lane region 3200. In such embodiments, the pixel openings 4310 may be exposed toward the deposition source 2200 through the buffer openings 4230 and the cell openings 4110, and the vapor deposition material provided from the deposition source 2200 during the deposition process may be deposited on the first electrodes AND of the backplane substrate 3000 through the cell openings 4110, the buffer openings 4230 and the pixel openings 4310.

According to one or more embodiments, as shown in FIG. 17, the membranes 4300 may be arranged in a matrix form along the first direction DR1 and the second direction DR2. For example, the first direction DR1 may be the first horizontal direction, and the second direction DR2 may be the second horizontal direction normal (e.g., perpendicular) to the first direction DR1. The pixel openings 4310 may be arranged to correspond to the first electrodes AND of the display cell regions 3100. As an example, the pixel openings 4310 may be arranged to correspond to the first electrodes AND of the first emission areas EA1, the second emission areas EA2, and the third emission areas EA3, as illustrated, for example, in FIGS. 9 and 10. In some embodiments, the pixel openings 4310 may be arranged to correspond to the first electrodes AND of any one or more of the first emission areas EA1, the second emission areas EA2, and/or the third emission areas EA3, as illustrated in FIG. 11.

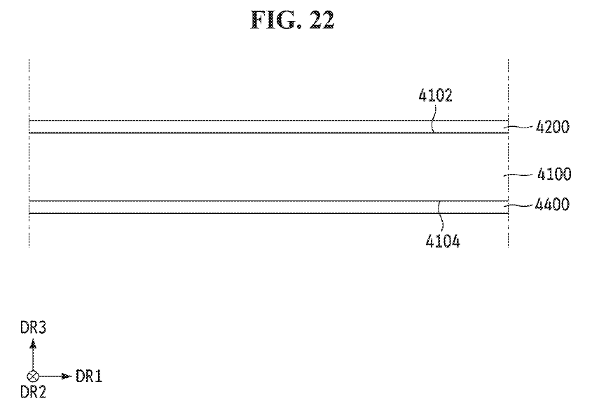

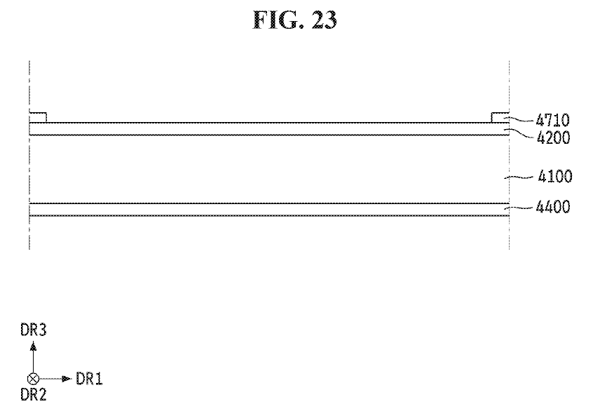

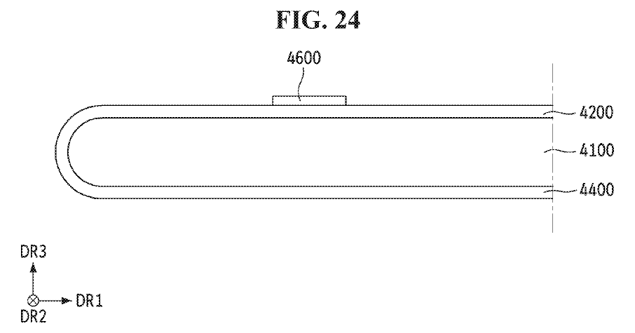

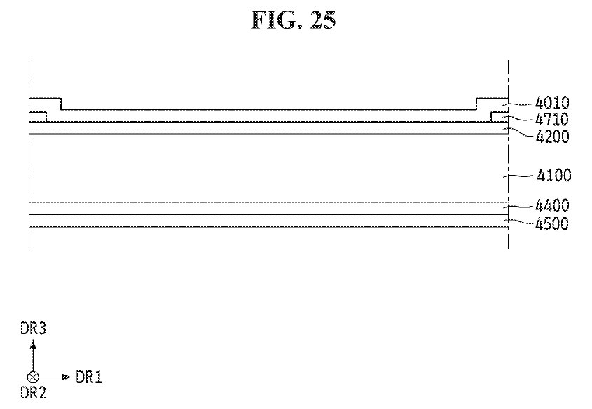

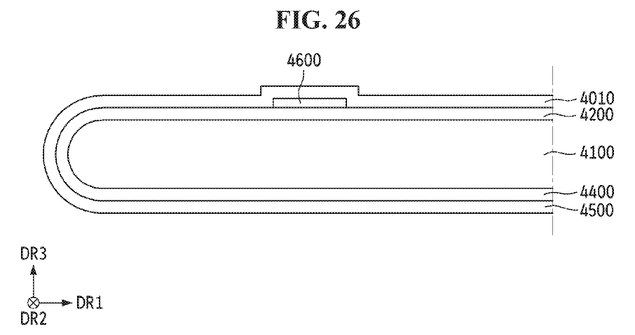

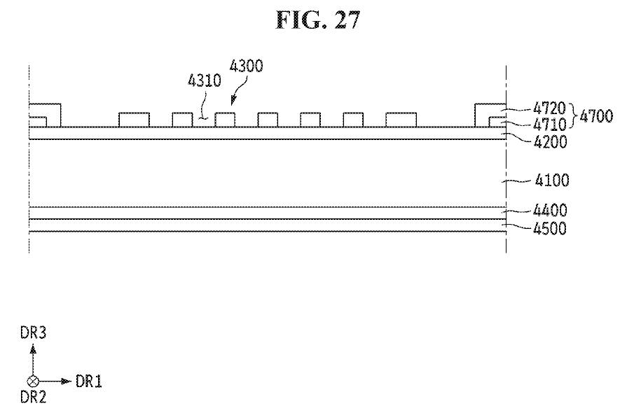

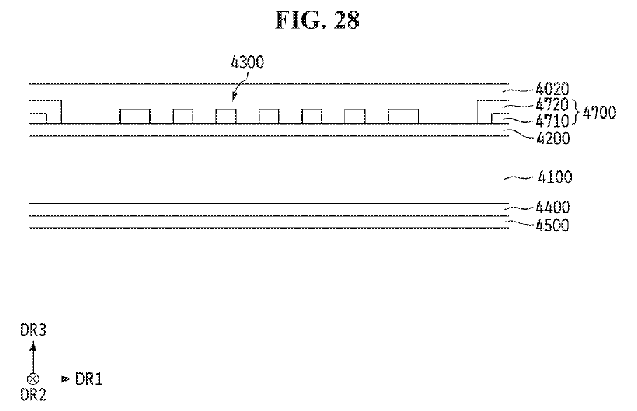

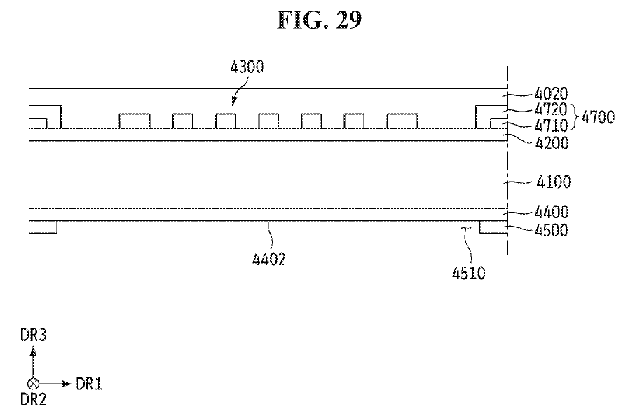

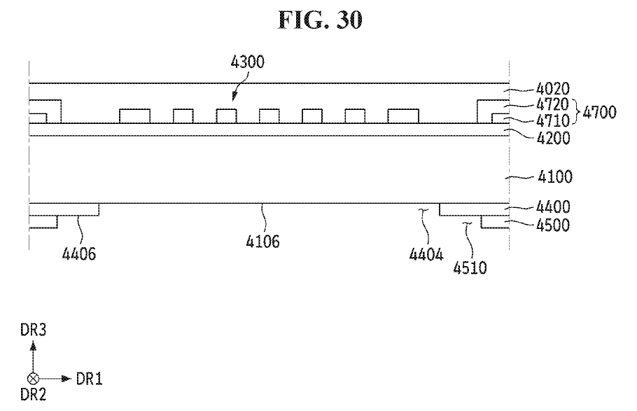

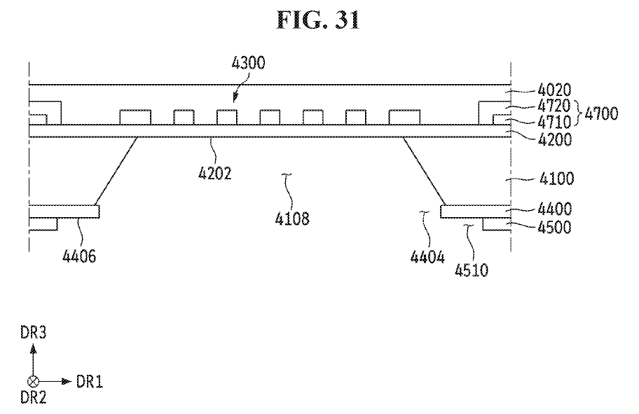

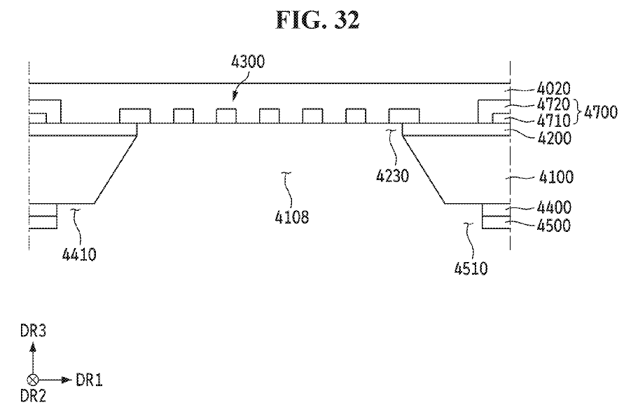

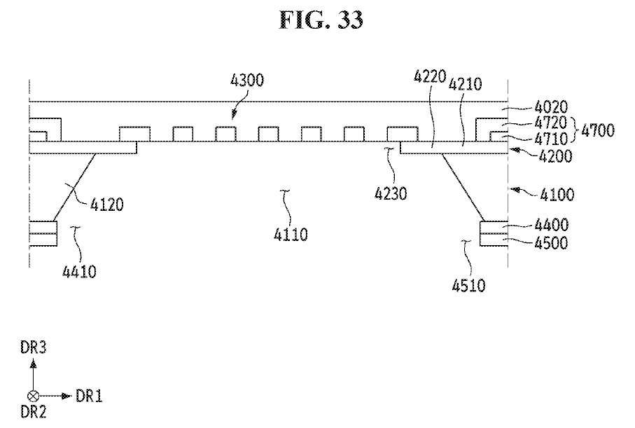

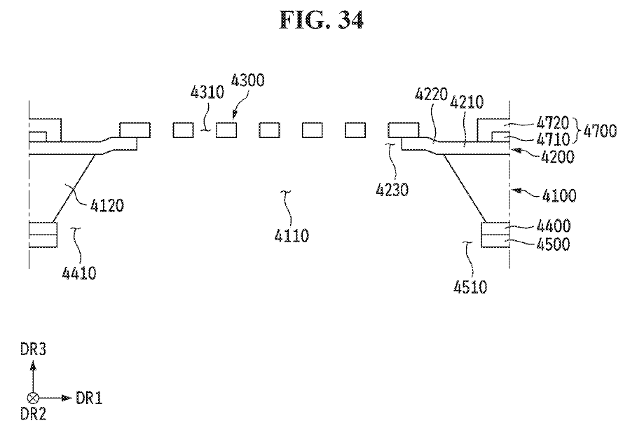

According to one or more embodiments, the buffer inorganic film 4200 and the membranes 4300 may be located on a front surface 4102 (see, e.g., FIG. 22) of the mask substrate 4100, and an intermediate inorganic film 4400 and a rear inorganic film 4500 may be located on a rear surface 4104 (see, e.g., FIG. 22) of the mask substrate 4100. For example, the intermediate inorganic film 4400 may be located on the rear surface 4104 of the mask substrate 4100, and the rear inorganic film 4500 may be located on the intermediate inorganic film 4400.

According to one or more embodiments, the intermediate inorganic film 4400 and the rear inorganic film 4500 may respectively have intermediate openings 4410 and rear openings 4510 that communicate with the cell openings 4110. According to one or more embodiments, the intermediate inorganic film 4400 and the rear inorganic film 4500 may function as an etching mask in an etching process for forming the cell openings 4110. In such embodiments, the pixel openings 4310 may be exposed toward the deposition source 2200 through the buffer openings 4230, the cell openings 4110, the intermediate openings 4410, and the rear openings 4510. In one or more embodiments, the vapor deposition material provided from the deposition source 2200 during the deposition process may be deposited on the first electrodes AND of the backplane substrate 3000 through the rear openings 4510, the intermediate openings 4410, the cell openings 4110, the buffer openings 4230, and the pixel openings 4310.

According to one or more embodiments, the cell openings 4110 may be formed by an anisotropic etching process using the intermediate inorganic film 4400 and the rear inorganic film 4500 as an etching mask. For example, a single crystal silicon substrate may be used as the mask substrate 4100, and the cell openings 4110 may be formed by a wet etching process using an etchant such as a tetramethylammonium hydroxide (TMAH) solution, or a potassium hydroxide (KOH) solution. In such embodiments, the <100> crystal direction of the single crystal silicon substrate used as the mask substrate 4100 may correspond to the third direction DR3, and accordingly, the cell openings 4110 formed by the wet etching process may have a width that gradually decreases from the rear surface 4104 of the mask substrate 4100 toward the front surface 4102 of the mask substrate 4100. For example, the inner side surfaces of the cell openings 4110 may have an inclination angle of about 54.7° with respect to the rear surface of the mask substrate 4100.

According to one or more embodiments, the buffer openings 4230 of the buffer inorganic film 4200 may be formed by a wet etching process. For example, if (e.g., when) the buffer inorganic film 4200 includes silicon oxide (SiOₓ), the buffer openings 4230 may be formed by a wet etching process using an etchant such as buffered oxide etchant (BOE) or diluted HF.

According to one or more embodiments, the buffer inorganic film 4200 and the intermediate inorganic film 4400 may include a material having an etching selectivity with respect to the mask substrate 4100. For example, the buffer inorganic film 4200 and the intermediate inorganic film 4400 may each include silicon oxide (SiOₓ) having residual compressive stress. For example, the buffer inorganic film 4200 and the intermediate inorganic film 4400 may be formed on the front surface 4102 and the rear surface 4104 of the mask substrate 4100 by a thermal oxidation process or a chemical vapor deposition (CVD) process, and may each have a thickness in a range of about 0.2 μm to about 2 μm.

According to one or more embodiments, the membranes 4300 and the rear inorganic film 4500 may include a material having an etching selectivity with respect to the buffer inorganic film 4200, the intermediate inorganic film 4400, and the mask substrate 4100. For example, the membranes 4300 and the rear inorganic film 4500 may each include silicon nitride (SiNₓ) having residual tensile stress. For example, the membranes 4300 and the rear inorganic film 4500 may each be formed to have a thickness of about 0.3 μm to about 3 μm by a low pressure chemical vapor deposition (LPCVD) process.

According to one or more embodiments, the eaves regions 4220 of the buffer inorganic film 4200 may be regions exposed by the cell openings 4110. For example, the eaves regions 4220 may be defined by the inner surfaces defining (of) the cell openings 4110 and the inner surfaces defining (of) the buffer openings 4230. According to one or more embodiments, a width w1 of the eaves regions 4220 may be greater than a width w2 of the regions where the edge regions of the membranes 4300 overlap the eaves regions 4220. According to one or more embodiments, the eaves regions 4220 may each have the width w1 of about 1 μm to about 100 μm, and the width w2 of the regions where the edge regions of the membranes 4300 and the eaves regions 4220 overlap each other in the thickness direction of the mask substrate 4100, for example, the third direction DR3, may each be in a range of about 0.5 μm to about 50 μm. By way of example, the width w1 of the eaves regions 4220 may each range from about 10 μm to about 30 μm, and the width w2 of the regions where the edge regions of the membranes 4300 and the eaves regions 4220 overlap each other may each be in a range of about 5 μm to about 15 μm.

According to one or more embodiments, if (e.g., when) the membranes 4300 are located on the eaves regions 4220 of the buffer inorganic film 4200 and the buffer inorganic film 4200 has residual compressive stress, the eaves regions 4220 of the buffer inorganic film 4200 may protrude in the third direction DR3 from the front surface 4102 of the mask substrate 4100 due to the residual compressive stress (see, e.g., the upward bend of the eaves regions 4220 in FIG. 19). For example, the eaves regions 4220 may extend from the grid region 4210 and be positioned higher than the grid region 4210. For example, the eaves regions 4220 of the buffer inorganic film 4200 may be lifted upwards in the third direction DR3 as illustrated in FIG. 19. When the membranes 4300 have residual tensile stress, deformation of the membranes 4300 may occur due to the residual tensile stress. However, according to one or more embodiments of the present disclosure, if (e.g., when) the edge portions of the membranes 4300 are located on the eaves regions 4220 of the buffer inorganic film 4200, the deformation of the membranes 4300 due to the residual tensile stress may be reduced by the deformation of the eaves regions 4220 due to the residual compressive stress. As a result, the membranes 4300 may be maintained in a flat state due to the deformation of the eaves regions 4220 as illustrated in FIG. 19. Thus, the cell warpage of the deposition mask 4000 may be reduced by the residual compressive stress of the buffer inorganic film 4200 and the residual tensile stress of the membranes 4300.

Unlike the above, if (e.g., when) the buffer inorganic film 4200 and the membranes 4300 have the same residual stress, for example, if (e.g., when) both the buffer inorganic film 4200 and the membranes 4300 have residual compressive stress, a moment may be generated in the third direction DR3 at the portions where the eaves regions 4220 of the buffer inorganic film 4200 and the edge portions of the membranes 4300 overlap each other. In such instances, a deformation may occur in which the membranes 4300 protrude convexly from the mask substrate 4100 in the third direction DR3. In view of this, it is not desirable for the buffer inorganic film 4200 and the membranes 4300 to have the same residual stress. For example, it is not desirable that the membranes 4300 both have residual compressive stress.

According to one or more embodiments, the membranes 4300 may include silicon-rich (Si-rich) silicon nitride having a silicon content (e.g., amount) higher than that of stoichiometric silicon nitride (Si₃N₄)_{.} For example, if the silicon content (e.g., amount) of the membranes 4300 is equal to or lower than that of the stoichiometric silicon nitride (Si₃N₄), the residual tensile stress of the membranes 4300 may increase, thereby causing global warpage in the deposition mask 4000. According to one or more embodiments, in order to reduce global warpage of the deposition mask 4000, the residual tensile stress of the membranes 4300 may be about 500 MPa or less, and the membranes 4300 may include silicon-rich silicon nitride.

For example, if (e.g., when) silicon nitride is expressed as SiₓN_{y}, where the ratio of the silicon content (e.g., amount) to the nitrogen content (e.g., amount) of the silicon nitride is referred to as an ‘x/y’ value, and the ratio of the silicon content (e.g., amount) to the nitrogen content (e.g., amount) of the stoichiometric silicon nitride (Si₃N₄), that is, the ‘x/y’ value of Si₃N₄, is 0.75. According to one or more embodiments, the ratio of the silicon content (e.g., amount) to the nitrogen content (e.g., amount) of the membranes 4300 may be controlled or selected to be within a range of about 0.8 to about 1.2.

According to one or more embodiments, the rear inorganic film 4500 may include the same material as the membranes 4300. For example, the rear inorganic film 4500 may be formed by an LPCVD process and may have the same thickness as the membranes 4300. According to one or more embodiments, the area of the rear inorganic film 4500 may be approximately equal to the sum of the areas of the membranes 4300. Accordingly, the force applied to the mask substrate 4100 due to the residual tensile stress of the membranes 4300 and the force applied to the mask substrate 4100 due to the residual tensile stress of the rear inorganic film 4500 may become substantially equal to or substantially similar to each other, and thus the global warpage of the deposition mask 4000 may be reduced.

According to one or more embodiments, as illustrated, for example, in FIG. 17, the deposition mask 4000 may include mask alignment keys 4600. For example, the mask alignment keys 4600 may be located on the edge portions of the deposition mask 4000 and used for positional alignment between the backplane substrate 3000 and the deposition mask 4000. In FIG. 17, two mask alignment keys 4600 are used, but the number of the mask alignment keys 4600 may be varied, and accordingly, the scope of the present disclosure is not limited to a particular number of mask alignment keys 4600.

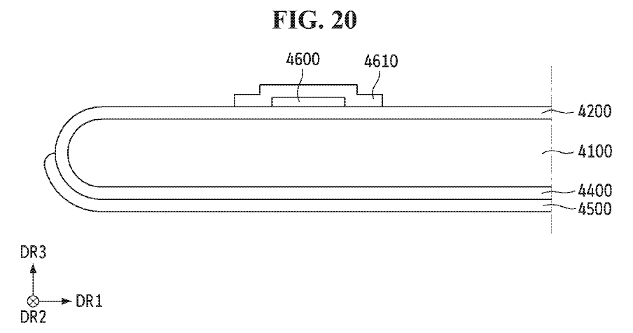

FIG. 20 is a schematic cross-sectional view illustrating the mask alignment keys of FIG. 17, according to one or more embodiments of the present disclosure.

Referring to FIG. 20, the mask alignment keys 4600 may be located on the edge portions of the mask substrate 4100. According to one or more embodiments, the mask alignment keys 4600 may be positioned on the edge portions of the buffer inorganic film 4200. In one or more embodiments, the mask alignment keys 4600 may include a metal such as copper (Cu), aluminum (Al), tungsten (W), molybdenum (Mo), chromium (Cr), gold (Au), titanium (Ti), nickel (Ni), neodymium (Nd), cobalt (Co), and/or the like, and may be formed by forming a metal film on the buffer inorganic film 4200 and then patterning the metal film.

According to one or more embodiments, the deposition mask 4000 may include protective film patterns 4610 arranged on the mask alignment keys 4600. According to one or more embodiments, the protective film patterns 4610 may include the same material as the membranes 4300 and may have the same thickness as the membranes 4300. For example, a front inorganic film 4010 (see, e.g., FIGS. 25 and 26) may be formed on the buffer inorganic film 4200 and the mask alignment keys 4600, and the membranes 4300 and the protective film patterns 4610 may be formed by patterning the front inorganic film 4010.

Referring again to FIGS. 17 - 19, the deposition mask 4000 may include spacer patterns 4700. According to one or more embodiments, the spacer patterns 4700 may be arranged on the grid region 4210 of the buffer inorganic film 4200. The spacer patterns 4700 may be used to prevent or reduce the likelihood of damage to the membranes 4300 that might be caused by contact with the backplane substrate 3000 during the deposition process.

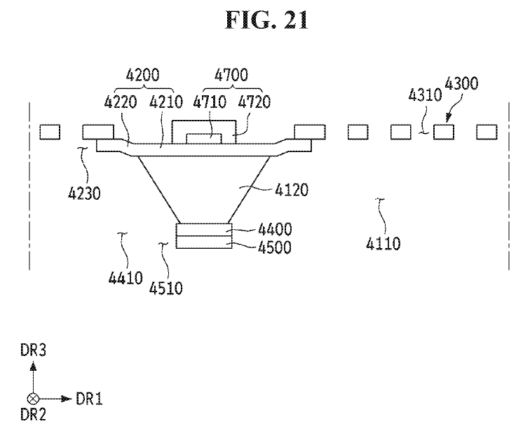

FIG. 21 is a schematic cross-sectional view illustrating the spacer patterns of FIG. 17, according to one or more embodiments of the present disclosure.

Referring to FIG. 21, each of the spacer patterns 4700 may include a first spacer pattern 4710 located on the grid region 4210 of the buffer inorganic film 4200 and a second spacer pattern 4720 located on the first spacer pattern 4710. According to one or more embodiments, the first spacer patterns 4710 may include the same material as the mask alignment keys 4600. For example, by forming a metal film on the buffer inorganic film 4200 and then patterning the metal film, the mask alignment keys 4600 and the first spacer patterns 4710 may be formed concurrently (e.g., simultaneously). In such embodiments, the mask alignment keys 4600 and the first spacer patterns 4710 may include substantially the same material and may have substantially the same thickness.

According to one or more embodiments, the second spacer patterns 4720 may include the same material as the membranes 4300. For example, the front inorganic film 4010 may be formed on the buffer inorganic film 4200, the mask alignment keys 4600, and the first spacer patterns 4710, and by patterning the front inorganic film 4010, the membranes 4300, the protective film patterns 4610, and the second spacer patterns 4720 may be formed concurrently (e.g., simultaneously). In such embodiments, the membranes 4300, the protective film patterns 4610, and the second spacer patterns 4720 may all include substantially the same material and may all have substantially the same thickness.

According to one or more embodiments, the top surfaces of the second spacer patterns 4720 may have the same height as the top surfaces of the membranes 4300 or may have a height higher than the top surfaces of the membranes 4300. Accordingly, during the deposition process, the membranes 4300 may not come into contact with the backplane substrate 3000, or even if the membranes 4300 come into contact with the backplane substrate 3000, damage to the membranes 4300 due to contact with the backplane substrate 3000 may be reduced. According to one or more embodiments, the first spacer patterns 4710 may have a thickness equal to or greater than the height to which the eaves regions 4220 are lifted by the residual compressive stress of the buffer inorganic film 4200. For example, the first spacer patterns 4710 may have a thickness of about 0.5 μm to about 3 μm.

FIGS. 22 - 34 are schematic cross-sectional views illustrating a method of manufacturing a deposition mask according to one or more embodiments of the present disclosure.

Referring to FIG. 22, the buffer inorganic film 4200 may be formed on the front surface 4102 of the mask substrate 4100. According to one or more embodiments, the mask substrate 4100 may include single crystal silicon. For example, a single crystal silicon substrate having a thickness in a range of about 700 μm to about 800 μm, e.g., about 725 μm or about 775 μm, may be used as the mask substrate 4100.

According to one or more embodiments, the buffer inorganic film 4200 may include silicon oxide (SiOₓ). The buffer inorganic film 4200 may be formed with a thickness of about 0.2 μm to about 2 μm on the front surface 4102 of the mask substrate 4100 by a thermal oxidation process or a CVD process.

The intermediate inorganic film 4400 may be formed on the rear surface 4104 of the mask substrate 4100. According to one or more embodiments, the intermediate inorganic film 4400 may include silicon oxide (SiOₓ). For example, the intermediate inorganic film 4400 may be formed on the rear surface 4104 of the mask substrate 4100 with a thickness of about 0.2 μm to about 2 μm by a thermal oxidation process or a CVD process. For example, the intermediate inorganic film 4400 may be formed concurrently (e.g., simultaneously) with the buffer inorganic film 4200 by a thermal oxidation process or a CVD process.

Referring to FIGS. 23 and 24, the mask alignment keys 4600 and the first spacer patterns 4710 may be formed on the buffer inorganic film 4200. According to one or more embodiments, the mask alignment keys 4600 may be formed on the edge portions of the buffer inorganic film 4200, and the first spacer patterns 4710 may be formed on the grid region 4210 (see, e.g., FIG. 21) of the buffer inorganic film 4200. For example, by forming a metal film on the buffer inorganic film 4200 and then patterning the metal film, the mask alignment keys 4600 and the first spacer patterns 4710 may be formed concurrently (e.g., simultaneously).

In one or more embodiments, the metal film may include a metal such as copper (Cu), aluminum (Al), tungsten (W), molybdenum (Mo), chromium (Cr), gold (Au), titanium (Ti), nickel (Ni), neodymium (Nd), cobalt (Co), and/or the like, and may be formed with a thickness of about 0.5 μm to about 3 μm by a sputtering process. Subsequently, a photoresist pattern may be formed on the metal film to expose portions of the metal film except the portions where the mask alignment keys 4600 and the first spacer patterns 4710 are to be formed, and an anisotropic etching process, for example, a plasma etching process, may be performed using the photoresist pattern as an etching mask, thereby forming the mask alignment keys 4600 and the first spacer patterns 4710 on the buffer inorganic film 4200. The photoresist pattern may be removed by an ashing and/or stripping process after the mask alignment keys 4600 and the first spacer patterns 4710 are formed.

Referring to FIGS. 25 and 26, the front inorganic film 4010 may be formed on the buffer inorganic film 4200, the mask alignment keys 4600, and the first spacer patterns 4710. According to one or more embodiments, the front inorganic film 4010 may include silicon nitride (SiNₓ) and may be conformally formed to have a thickness of about 0.3 μm to about 3 μm by an LPCVD process. For example, a silicon source gas such as monosilane (SiH₄) or dichlorosilane (DCS) and a nitrogen source gas such as nitrogen (N₂) or ammonia (NH₃) may be supplied to (onto) the buffer inorganic film 4200, the mask alignment keys 4600, and the first spacer patterns 4710, and the front inorganic film 4010 may be formed by a reaction between the silicon source gas and the nitrogen source gas.

The rear inorganic film 4500 may be formed on the intermediate inorganic film 4400. According to one or more embodiments, the rear inorganic film 4500 may include silicon nitride (SiNₓ) and may be formed on the intermediate inorganic film 4400 to have a thickness of about 0.3 μm to about 3 μm through an LPCVD process. For example, the front inorganic film 4010 and the rear inorganic film 4500 may be formed concurrently (e.g., simultaneously) by an LPCVD process. In such embodiments, the rear inorganic film 4500 may have the substantially the same thickness as the front inorganic film 4010.

According to one or more embodiments, the front inorganic film 4010 may include Si-rich silicon nitride having a silicon content (e.g., amount) higher than that of stoichiometric silicon nitride (Si₃N₄)_{.} According to one or more embodiments, the ratio of the silicon content (e.g., amount) to the nitrogen content (e.g., amount) of the front inorganic film 4010 may be controlled or selected to be within a range of about 0.8 to about 1.2. For example, the LPCVD process may be performed at a low pressure and a high temperature to form a silicon-rich silicon nitride film. For example, the LPCVD process may be performed in a pressure atmosphere of about 210 mTorr to about 250 mTorr and a temperature atmosphere of about 800° C to about 850° C. According to one or more embodiments, if (e.g., when) the rear inorganic film 4500 is formed concurrently (e.g., simultaneously) with the front inorganic film 4010, the ratio of the silicon content (e.g., amount) to the nitrogen content (e.g., amount) of the rear inorganic film 4500 may be substantially the same as the ratio of the silicon content (e.g., amount) to the nitrogen content (e.g., amount) of the front inorganic film 4010.

Referring to FIG. 27, the front inorganic film 4010 may be patterned to form the membranes 4300 and the pixel openings 4310 penetrating the membranes 4300 on the buffer inorganic film 4200. Additionally, the front inorganic film 4010 may be patterned to form the protective film patterns 4610 (see, e.g., FIG. 20) and the second spacer patterns 4720 (see, e.g., FIG. 21) on the mask alignment keys 4600 and the first spacer patterns 4710, respectively. For example, a photoresist pattern may be formed on the front inorganic film 4010 to expose the portions where the pixel openings 4310 are to be formed and to expose the portions of the front inorganic film 4010 except where the membranes 4300, the protective film patterns 4610, and the second spacer patterns 4720 are to be formed, and an anisotropic etching process, for example, a plasma etching process or a reactive ion etching (RIE) process, may be performed using the photoresist pattern as an etching mask, thereby forming the membranes 4300, the protective film patterns 4610, the second spacer patterns 4720, and the pixel openings 4310.

For example, if (e.g., when) the front inorganic film 4010 includes silicon nitride (SiNₓ), the anisotropic etching process may be performed using a first reactive gas containing fluorine, such as CF₄, C₂F₄, C₂F₆, C₃F₆, C₃F₈, C₄F₆, C₄F₈, CH₃F, CH₂F₂, C₂HF₅, CHF₃, NF₃, or SF₆, a second reactive gas containing oxygen, such as O₂, NO, or NO₂, and a sputtering gas, such as He, Ne, Ar, or Xe, until the buffer inorganic film 4200 is exposed. The photoresist pattern may be removed by an ashing and/or stripping process after the membranes 4300, the protective film patterns 4610, the second spacer patterns 4720, and the pixel openings 4310 are formed.

Referring to FIG. 28, an etch stop film 4020 may be formed on the buffer inorganic film 4200, the membranes 4300, the protective film patterns 4610, and the second spacer patterns 4720. According to one or more embodiments, the etch stop film 4020 may include a photoresist or an organic insulating material such as acrylic resin, epoxy resin, phenolic resin, polyamide resin, polyimide resin, unsaturated polyester resin, polyphenylene ether resin, polyphenylenesulfide resin or benzocyclobutene (BCB), and may be formed through a spin coating process and a bake process.

Referring to FIG. 29, the rear inorganic film 4500 may be partially removed to form the rear openings 4510. According to one or more embodiments, the rear inorganic film 4500 may be patterned to form the rear openings 4510 that partially expose the intermediate inorganic film 4400. In such embodiments, portions 4402 of the intermediate inorganic film 4400 that are exposed by the rear openings 4510 may overlap the membranes 4300 in the thickness direction of the mask substrate 4100, for example, in the third direction DR3. For example, after forming on the rear inorganic film 4500 a photoresist pattern that exposes portions where the rear openings 4510 are to be formed, an anisotropic etching process, for example, a plasma etching process or an RIE process, may be performed using the photoresist pattern as an etching mask, thereby forming the rear openings 4510 penetrating the rear inorganic film 4500.

By way of example, if (e.g., when) the rear inorganic film 4500 includes silicon nitride (SiNₓ), the anisotropic etching process may be performed using a first reactive gas including fluorine, such as CF₄, C₂F₄, C₂F₆, C₃F₆, C₃F₈, C₄F₆, C₄F₈, CH₃F, CH₂F₂, C₂HF₅, CHF₃, NF₃, or SF₆, a second reactive gas including oxygen, such as O₂, NO, or NO₂, and a sputtering gas, such as He, Ne, Ar, or Xe, until the intermediate inorganic film 4400 is exposed, thereby forming the rear openings 4510. The photoresist pattern may be removed by an ashing and/or stripping process after the rear openings 4510 are formed.

Referring to FIG. 30, the intermediate inorganic film 4400 may be partially removed to form preliminary intermediate openings 4404. According to one or more embodiments, the intermediate inorganic film 4400 may be patterned to form the preliminary intermediate openings 4404 that partially expose the rear surface 4104 (see, e.g., FIG. 22) of the mask substrate 4100. According to one or more embodiments, the preliminary intermediate openings 4404 may have a smaller width than the rear openings 4510 and may be formed to penetrate portions 4402 of the intermediate film 4400 exposed by the rear openings 4510. For example, after a photoresist pattern that exposes portions where the preliminary intermediate openings 4404 are to be formed is formed on the portions 4402 of the intermediate inorganic film 4440 that are exposed by the rear inorganic film 4500 and the rear openings 4510, an anisotropic etching process, for example, a plasma etching process or an RIE process, may be performed using the photoresist pattern as an etching mask to form the preliminary intermediate openings 4404 penetrating the intermediate inorganic film 4400.

For example, if (e.g., when) the intermediate inorganic film 4400 includes silicon oxide (SiOₓ), the anisotropic etching process may be performed using a reactive gas containing fluorine, such as CF₄, C₂F₄, C₂F₆, C₃F₆, C₃F₈, C₄F₆, C₄F₈, CH₃F, CH₂F₂, C₂HF₅, CHF₃, NF₃, or SF₆, and a sputtering gas, such as He, Ne, Ar, or Xe, until the rear surface 4104 of the mask substrate 4100 is exposed, thereby forming the preliminary intermediate openings 4404. The photoresist pattern may be removed by an ashing and/or stripping process after the preliminary intermediate openings 4404 are formed.

According to one or more embodiments, portions 4406 of the intermediate inorganic film 4400 between the inner surfaces defining (of) the preliminary intermediate openings 4404 and the inner surfaces defining (of) the rear openings 4510, i.e., the portions 4406 of the intermediate inorganic film 4400 exposed by the rear openings 4510 after the preliminary intermediate openings 4404 are formed, may have a constant width in the first direction DR1 and the second direction DR2 (e.g., the inner surfaces of the rear openings 4510 and inner surfaces of the preliminary intermediate openings 4404 may be substantially parallel to the thickness direction of the mask substrate 4100, i.e., in the third direction DR3). Additionally, rear portions 4106 of the mask substrate 4100 that are exposed by the preliminary intermediate openings 4404 may overlap the membranes 4300 in the thickness direction of the mask substrate 4100, i.e., the third direction DR3.

Referring to FIG. 31, the mask substrate 4100 may be partially removed, that is, partially patterned to form preliminary cell openings 4108 that expose the buffer inorganic film 4200. In one or more embodiments, the preliminary cell openings 4108 may be formed through an anisotropic etching process using the rear inorganic film 4500 and the intermediate inorganic film 4400 as an etching mask. For example, the preliminary cell openings 4108 may be formed by a first wet etching process using an etchant such as a TMAH solution, a KOH solution, and/or the like, and the first wet etching process may be performed until the buffer inorganic film 4200 is exposed.

According to one or more embodiments, the <100> crystal direction of the single crystal silicon substrate used as the mask substrate 4100 may correspond to the third direction DR3, and accordingly, the preliminary cell openings 4108 formed by the first wet etching process may have a width that gradually decreases from the rear surface 4104 of the mask substrate 4100 toward the front surface 4102 of the mask substrate 4100. For example, the inner side surfaces of the preliminary cell openings 4108 may have an inclination angle of about 54.7° with respect to the rear surface 4104 of the mask substrate 4100.

According to one or more embodiments, portions 4202 of the buffer inorganic film 4200 that are exposed by the preliminary cell openings 4108 may overlap the membranes 4300 in the thickness direction of the mask substrate 4100, i.e., the third direction DR3. For example, the portions 4202 of the buffer inorganic film 4200 that are exposed by the preliminary cell openings 4108 may overlap the portions of the membranes 4300 where the pixel openings 4310 are formed in the thickness direction of the mask substrate 4100.

Referring to FIG. 32, the portions 4202 of the buffer inorganic film 4200 exposed by the preliminary cell openings 4108 may be removed. In one or more embodiments, the portions 4202 of the buffer inorganic film 4200 exposed by the preliminary cell openings 4108 may be removed to form buffer openings 4230 that partially expose the membranes 4300. In one or more embodiments, the buffer openings 4230 may expose the portions of the membranes 4300 where the pixel openings 4310 are formed, and the edge portions of the membranes 4300 may remain on the buffer inorganic film 4200. For example, the edge portions of the membranes 4300 may remain on the eaves regions 4220 (see FIGS. 19 and 21) of the buffer inorganic film 4200. For example, if (e.g., when) the buffer inorganic film 4200 includes silicon oxide (SiOₓ), the buffer openings 4230 may be formed by a second wet etching process using an etchant such as BOE, diluted hydrofluoric acid, and/or the like.

According to one or more embodiments, the portions 4406 of the intermediate inorganic film 4400 that are exposed by the rear openings 4510 may be removed by the second wet etching process, thereby forming the intermediate openings 4410. For example, if (e.g., when) the intermediate inorganic film 4400 includes silicon oxide (SiOₓ), the preliminary intermediate openings 4404 may be expanded by the second wet etching process, thereby forming the intermediate openings 4410 having approximately the same size as the rear openings 4510.

According to one or more embodiments, the etch stop film 4020 may prevent or reduce the likelihood of the grid region 4210 (see, e.g., FIGS. 19 and 21) and the eaves regions 4220 of the buffer inorganic film 4200 from being etched during the second wet etching process. For example, only the portions 4202 of the buffer inorganic film 4200 that are exposed by the preliminary cell openings 4108 and the portions 4406 of the intermediate inorganic film 4400 that are exposed by the rear openings 4510 may be selectively removed by the second wet etching process.

Referring to FIG. 33, the cell openings 4110 may be formed by expanding the preliminary cell openings 4108 to expose the eaves regions 4220 of the buffer inorganic film 4200. According to one or more embodiments, by removing the inner surface portions defining (of) the preliminary cell openings 4108, the cell openings 4110 may be formed, and beside them, the rib region 4120 defining the cell openings 4110 may be formed. For example, the cell openings 4110 may be formed by a third wet etching process using an etchant such as a TMAH solution, a KOH solution, and/or the like, and the inner side surfaces of the cell openings 4110 may have an inclination angle of about 54.7° with respect to the rear surface 4104 of the mask substrate 4100.

According to one or more embodiments, the eaves regions 4220 of the buffer inorganic film 4200 may be regions extending from the rib region 4120 of the mask substrate 4100 toward the inside of the cell openings 4110, and the grid region 4210 of the buffer inorganic film 4200 may be a region located on the rib region 4120 of the mask substrate 4100. According to one or more embodiments, the width w1 (see, e.g., FIG. 19) of each of the eaves regions 4220 may be greater than the width w2 (see, e.g., FIG. 19) of each of the regions where the edge regions of the membranes 4300 and the eaves regions 4220 overlap each other in the thickness direction of the mask substrate 4100. According to one or more embodiments, the eaves regions 4220 may each have the width w1 of about 1 μm to about 100 μm, and the width w2 of the regions where the edge regions of the membranes 4300 and the eaves regions 4220 overlap each other may each be in a range of about 0.5 μm to about 50 μm. For example, the width w1 of each of the eaves regions 4220 may be about 10 μm to about 30 μm, and the width w2 of each of the regions where the edge regions of the membranes 4300 and the eaves regions 4220 overlap each other may be about 5 μm to about 15 μm.

Referring to FIG. 34, the etch stop film 4020 may be removed, thereby connecting the pixel openings 4310 to the buffer openings 4230. According to one or more embodiments, if (e.g., when) the etch stop film 4020 is removed, the eaves regions 4220 of the buffer inorganic film 4200 may be lifted away from the front surface 4102 of the mask substrate 4100, for example, in the third direction DR3, due to the residual compressive stress of the buffer inorganic film 4200 and the residual tensile stress of the membranes 4300, and the membranes 4300 may be maintained in a flat state due to this deformation of the eaves regions 4220.

According to one or more embodiments, the etch stop film 4020 may be removed by a wet etching process, a plasma etching process, and/or the like. For example, if (e.g., when) the etch stop film 4020 includes an organic insulating material, the etch stop film 4020 may be removed by a fourth wet etching process using an etchant such as acetone, alcohol, toluene, propylene glycol, propylene glycol methyl acetate, triethylene glycol monobutyl ether, diethylene glycol monophenyl ether, an amide solvent, a dicarbonyl solvent, diethylene glycol dibenzoate, a tricarbonyl solvent, triethyl citrate, a phthalate solvent, benzyl butyl phthalate, bis(2-ethlyhexyl) phthalate, bis(2-ethylhexyl) isophthalate, ethyl phthalyl ethyl glycolate, or n-methyl-2-pyrrolidone (NMP). In one or more embodiments, if the etch stop film 4020 includes a photoresist, the etch stop film 4020 may be removed by an ashing and/or stripping process.

As described above, the etch stop film 4020 is removed after the cell openings 4110 are formed. However, unlike the above, the etch stop film 4020 may be removed after the buffer openings 4230 and the intermediate openings 4410 are formed. In such instances, the cell openings 4110 may be formed after the etch stop film 4020 is removed. When the etch stop film 4020 is removed before forming the cell openings 4110 as described above, the membranes 4300 may be deformed to some extent by residual tensile stress. However, if (e.g., when) the cell openings 4110 are subsequently formed, the membranes 4300 may be flattened by the eaves regions 4220 of the buffer inorganic film 4200 that are exposed by the cell openings 4110.

According to one or more embodiments of the present disclosure as described above, the deformation of the membranes 4300 may be reduced by the eaves regions 4220 of the buffer inorganic film 4200 (e.g., the residual compressive stress at the eaves regions 4220), and the deformation of the mask substrate 4100 may be reduced by controlling the areas of the membranes 4300 and the rear inorganic film 4500. As a result, the cell warpage and the global warpage of the deposition mask 4000 may be reduced, thus helping to improve accuracy in the deposition of light-emitting materials for a display device, leading to improved quality and resolution of the display device.

In addition, for example, the combined structural configuration and manufacturing sequence described herein not only mitigates warpage but also ensures precise alignment of pixel openings with underlying electrodes during vapor deposition. By integrating stress-balanced films, eaves regions, and optional spacer and alignment features, the deposition mask achieves dimensional stability critical for high-resolution OLED-on-silicon panels. These improvements collectively support reliable fabrication of advanced display devices, including AR/VR head-mounted displays and other compact electronics requiring ultra-high pixel density.

The deposition mask, display panel, electronic device, device for manufacturing the display device, device for manufacturing the deposition mask, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A deposition mask comprising:
a mask substrate defining a cell opening;
a buffer inorganic film on the mask substrate and comprising an eaves region exposed by the cell opening; and
a membrane on the eaves region and defining a plurality of pixel openings connected to the cell opening.

2. The deposition mask of claim 1, wherein the buffer inorganic film has residual compressive stress, and
the membrane has residual tensile stress.

3. The deposition mask of claim 1, wherein a width of the eaves region is in a range of 1 μm to 100 μm.

4. The deposition mask of claim 1, wherein an edge region of the membrane is on the eaves region, and
a width of a region where the edge region of the membrane and the eaves region overlap each other is in a range of 0.5 μm to 50 μm.

5. The deposition mask of claim 1, wherein the mask substrate comprises a rib region defining the cell opening,
the buffer inorganic film comprises a grid region on the rib region, and
the eaves region extends from the grid region and is positioned higher than the grid region.

6. The deposition mask of claim 5, further comprising a spacer pattern on the grid region.

7. The deposition mask of claim 6, wherein the spacer pattern comprises:
a first spacer pattern on the grid region; and
a second spacer pattern on the first spacer pattern, and
the second spacer pattern comprises a same material as the membrane.

8. The deposition mask of claim 7, further comprising a mask alignment key on an edge region of the buffer inorganic film,
wherein the first spacer pattern comprises a same material as the mask alignment key.

9. The deposition mask of claim 8, further comprising a protective film pattern on the mask alignment key,
wherein the protective film pattern comprises a same material as the membrane.

10. A method comprising:
forming a buffer inorganic film on a mask substrate;
forming a membrane having a plurality of pixel openings on the buffer inorganic film;
forming a preliminary cell opening that partially exposes the buffer inorganic film by partially removing the mask substrate;
forming a buffer opening that partially exposes the membrane by removing a portion of the buffer inorganic film exposed by the preliminary cell opening; and
forming a cell opening that partially exposes the buffer inorganic film by expanding the preliminary cell opening,
wherein the membrane is on an eaves region of the buffer inorganic film exposed by the cell opening, and
wherein the method is a method for manufacturing a deposition mask.

11. The method of claim 10, wherein the forming of the membrane comprises:
forming a front inorganic film on the buffer inorganic film; and
partially removing the front inorganic film to form the plurality of pixel openings and the membrane,
wherein the buffer inorganic film has residual compressive stress, and
the front inorganic film has residual tensile stress.

12. The method of claim 11, further comprising:
forming a mask alignment key on an edge region of the buffer inorganic film; and
forming a protective film pattern on the mask alignment key,
wherein the protective film pattern is formed concurrently with the plurality of pixel openings and the membrane by partially removing the front inorganic film.

13. The method of claim 12, further comprising:
forming a first spacer pattern on the buffer inorganic film; and
forming a second spacer pattern on the first spacer pattern,
wherein the first spacer pattern is formed concurrently with the mask alignment key, and
the second spacer pattern is formed concurrently with the protective film pattern.

14. The method of claim 10, wherein the buffer inorganic film is formed on a front surface of the mask substrate, and the forming of the preliminary cell opening comprises:
forming an intermediate inorganic film on a rear surface of the mask substrate;
forming a rear inorganic film on the intermediate inorganic film;
forming a rear opening that partially exposes the intermediate inorganic film through the rear inorganic film;
forming a preliminary intermediate opening that partially exposes the rear surface of the mask substrate through a portion of the intermediate inorganic film exposed by the rear opening; and
forming the preliminary cell opening by performing an etching process utilizing the rear inorganic film and the intermediate inorganic film as etching masks.

15. The method of claim 14, wherein the preliminary intermediate opening has a width smaller than that of the rear opening, and the forming of the cell opening comprises:
forming an intermediate opening by removing a remaining portion of the portion of the intermediate inorganic film exposed by the rear opening; and
expanding the preliminary cell opening by removing inner surface portions that define the preliminary cell opening.

16. The method of claim 15, wherein the forming of the intermediate opening is performed concurrently with the forming of the buffer opening.

17. The method of claim 10, further comprising:
forming an etch stop film on the buffer inorganic film and the membrane; and
removing the etch stop film after forming the buffer opening.

18. The method of claim 10, wherein an edge region of the membrane is located on the eaves region, and
a region where the edge region of the membrane and the eaves region overlap each other has a width smaller than that of the eaves region.

19. An electronic device comprising:
a display panel, wherein the display panel comprises a backplane substrate and a plurality of light-emitting layers formed on the backplane substrate by utilizing a deposition mask,
the deposition mask comprises:
a mask substrate defining a cell opening,
a buffer inorganic film on the mask substrate and comprising an eaves region exposed by the cell opening, and
a membrane on the eaves region and defining a plurality of pixel openings connected to the cell opening, and
the plurality of light-emitting layers are formed by a deposition process that provides a vapor light-emitting material onto the backplane substrate through the cell opening and the pixel openings.

20. The electronic device of claim 19, further comprising at least one of a processor, a memory, or a power module.
